(19) United States
(12) Patent Application Publication
(10) Pub. No.: US 2025/0372043 A1
(43) Pub. Date: Dec. 4, 2025

(54) DISPLAY APPARATUS AND VEHICLE INCLUDING THE SAME

(71) Applicant: Samsung Display Co., Ltd., Yongin-si (KR)

(72) Inventor: Changho Hyun, Yongin-si (KR)

(21) Appl. No.: 18/975,907

(22) Filed: Dec. 10, 2024

(30) Foreign Application Priority Data
May 30, 2024 (KR) 10-2024-0071000

(51) Int. Cl. G09G 3/3266; B60K 37/20

(52) U.S. Cl. CPC G09G 3/3266; B60K 37/20; G09G 2380/10

(57) ABSTRACT

A display apparatus includes a first display unit including a plurality of first pixels and light-blocking lines that are, in a plan view, located only on a first direction side of each of pixels of first pixels that are in odd-numbered columns, the light-blocking lines extending in a second direction crossing a first direction, a first driving circuit electrically connected to first gate lines configured to provide a first gate signal to the pixels of the first pixels that are in the odd-numbered columns, and a second driving circuit electrically connected to second gate lines configured to provide a second gate signal to pixels in even-numbered columns among the plurality of first pixels.

### CROSS-REFERENCE TO RELATED APPLICATION

The present application claims priority to and the benefit of Korean Patent Application No. 10-2024-0071000, filed on May 30, 2024, in the Korean Intellectual Property Office, the disclosure of which is incorporated by reference herein in its entirety.

### BACKGROUND

### 1. Field

Aspects of the present disclosure relate to a display apparatus and a vehicle including the same.

### 2. Description of the Related Art

Recently, display apparatuses are becoming ubiquitous. Because the thickness and weight of the display apparatuses have decreased, the use of the display apparatuses has widened, and as the display apparatuses are utilized in various fields, the demand for display apparatuses capable of providing high-quality images is increasing. Display apparatuses have been recently placed inside vehicles to provide images to users in the driver's seat or passenger's seat.

The above information disclosed in this Background section is only for enhancement of understanding of the background of the invention and therefore it may contain information that does not form the prior art.

### SUMMARY

Aspects of some embodiments of the present disclosure are directed to a display apparatus capable of producing high-quality images and a vehicle including the display apparatus. However, this is merely an example, and the scope of the present disclosure is not limited thereto.

Additional aspects will be set forth in part in the description which follows and, in part, will be apparent from the description, or may be learned by practice of the presented embodiments of the disclosure.

According to some embodiments of the present disclosure there is provided a display apparatus including: a first display unit including a plurality of first pixels and light-blocking lines that are, in a plan view, located only on a first direction side of each of pixels of first pixels that are in odd-numbered columns, the light-blocking lines extending in a second direction crossing a first direction; a first driving circuit electrically connected to first gate lines configured to provide a first gate signal to the pixels of the first pixels that are in the odd-numbered columns; and a second driving circuit electrically connected to second gate lines configured to provide a second gate signal to pixels in even-numbered columns among the plurality of first pixels.

In some embodiments, the plurality of first pixels include a plurality of first sub-pixels configured to emit first color light, a plurality of second sub-pixels configured to emit second color light, and a plurality of third sub-pixels configured to emit third color light, in the plurality of first sub-pixels are located in a third column and a fourth column, wherein, in a plan view, the plurality of second sub-pixels and the plurality of third sub-pixels are located in a first column and a second column, and wherein a set of a pair of second sub-pixels and a set of a pair of third sub-pixels are alternately arranged.

In some embodiments, the first driving circuit includes a 1^{st}-1^{st} driving circuit arranged on a first direction side of the first display unit and a 1^{st}-2^{nd} driving circuit arranged on a third direction side of the first display unit, a third direction being opposite to the first direction.

In some embodiments, in a cross-sectional view perpendicular to the second direction, the light-blocking lines have heights gradually decreasing in a third direction which is opposite to the first direction.

In some embodiments, the display apparatus further includes a controller, wherein, based on a first control signal from the controller, the first driving circuit is configured to provide a turn-on signal to the first gate lines, and the second driving circuit is configured to provide a turn-off signal to the second gate lines.

In some embodiments, based on a second control signal from the controller, the first driving circuit is configured to provide a turn-off signal to the first gate lines, and the second driving circuit is configured to provide a turn-on signal to the second gate lines.

In some embodiments, the first driving circuit and the second driving circuit include decoder-type driving circuits that individually drive the first gate lines and the second gate lines.

In some embodiments, the display apparatus further includes: a second display unit arranged on a side of the first display unit in the first direction and including a plurality of second pixels and light-blocking lines that are, in a plan view, positioned only on a third direction side of each of pixels in even-numbered columns among the plurality of second pixels, a third direction being opposite to the first direction, the light-blocking lines extending in the second direction; a third driving circuit electrically connected to third gate lines that are configured to provide a third gate signal to pixels of the first pixels that are in the odd-numbered columns; and a fourth driving circuit electrically connected to fourth gate lines that are configured to provide a fourth gate signal to the pixels in the even-numbered columns among the plurality of second pixels.

In some embodiments, the third driving circuit includes a 3^{rd}-1^{st} driving circuit arranged on a first direction side of the second display unit and a 3^{rd}-2^{nd} driving circuit arranged on the third direction side of the second display unit.

In some embodiments, in a cross-sectional view perpendicular to the second direction, the light-blocking lines have heights gradually increasing in the third direction.

In some embodiments, based on a third control signal from the controller, the third driving circuit is configured to provide a turn-off signal to the third gate lines, and the fourth driving circuit is configured to provide a turn-on signal to the fourth gate lines.

In some embodiments, based on a fourth control signal from the controller, the third driving circuit is configured to provide a turn-on signal to the third gate lines, and the fourth driving circuit is configured to provide a turn-off signal to the fourth gate lines.

In some embodiments, the third driving circuit and the fourth driving circuit include decoder-type driving circuits that individually drive the third gate lines and the fourth gate lines.

In some embodiments, the display apparatus further includes: a third display unit arranged between the first display unit and the second display unit and including a plurality of third pixels; and a fifth driving circuit arranged on an edge of the third display unit in a direction towards the first display unit or the second display unit, the fifth driving circuit being connected to fifth gate lines configured to provide a fifth gate signal to the plurality of third pixels.

In some embodiments, a vehicle includes the above-described display apparatus.

In some embodiments, the first display unit is arranged on a passenger side dashboard.

In some embodiments, a vehicle including the above-described display apparatus.

In some embodiments, the first display unit is arranged on a passenger side dashboard.

In some embodiments, the second display unit is arranged on a cluster in a driver's seat.

In some embodiments, the third display unit is arranged between the passenger side dashboard and the cluster in the driver's seat.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 schematically shows the exterior of a vehicle, according to some embodiments of the present disclosure;

FIGS. 2A to 2C schematically show the interior of a vehicle, according to some embodiments of the present disclosure;

FIG. 3 is a schematic perspective view of a display apparatus according to some embodiments of the present disclosure;

FIG. 4 is a schematic plan view of a display apparatus according to some embodiments of the present disclosure;

FIG. 5 is a schematic cross-sectional view of the display apparatus of FIG. 3, taken along the line A-A′ of FIG. 3, according to some embodiments of the present disclosure;

FIG. 6 schematically shows a display apparatus according to some embodiments of the present disclosure;

FIG. 7 is an equivalent circuit diagram of a pixel circuit according to some embodiments of the present disclosure;

FIG. 8A is an enlarged view of a first display area of a display apparatus, according to some embodiments;

FIG. 8B is a schematic cross-sectional view of the display apparatus of FIG. 8A, taken along the line II-II′ of FIG. 8A, according to some embodiments of the present disclosure;

FIG. 9A is an enlarged view of a second display area of a display apparatus, according to some embodiments of the present disclosure;

FIG. 9B is a schematic cross-sectional view of the display apparatus of FIG. 9A, taken along the line I-I′ of FIG. 9A, according to some embodiments of the present disclosure;

FIG. 10 is an enlarged view of a third display area of a display apparatus, according to some embodiments of the present disclosure; and

FIGS. 11A to 11C are diagrams showing a field of vision of the driver's seat and passenger seat in a driving mode, according to some embodiments of the present disclosure.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description.

As the disclosure allows for various changes and numerous embodiments, particular embodiments will be shown in the drawings and described in detail in the written description. The attached drawings for illustrating embodiments of the disclosure are referred to in order to gain a sufficient understanding of the present disclosure, the merits thereof, and the objectives accomplished by the implementation of the disclosure. The disclosure may, however, be embodied in many different forms and should not be construed as being limited to the embodiments set forth herein.

One or more embodiments of the present disclosure will be described more fully with reference to the accompanying drawings, like reference numerals in the drawings denote like elements, and repeated descriptions thereof will not be provided.

Sizes of elements in the drawings may be exaggerated for convenience of explanation. In other words, since sizes and thicknesses of elements in the drawings are arbitrarily illustrated for convenience of explanation, the following embodiments are not limited thereto.

When a certain embodiment may be implemented differently, a specific process order may be performed differently from the described order. For example, two consecutively described processes may be performed substantially at the same time or performed in an order opposite to the described order.

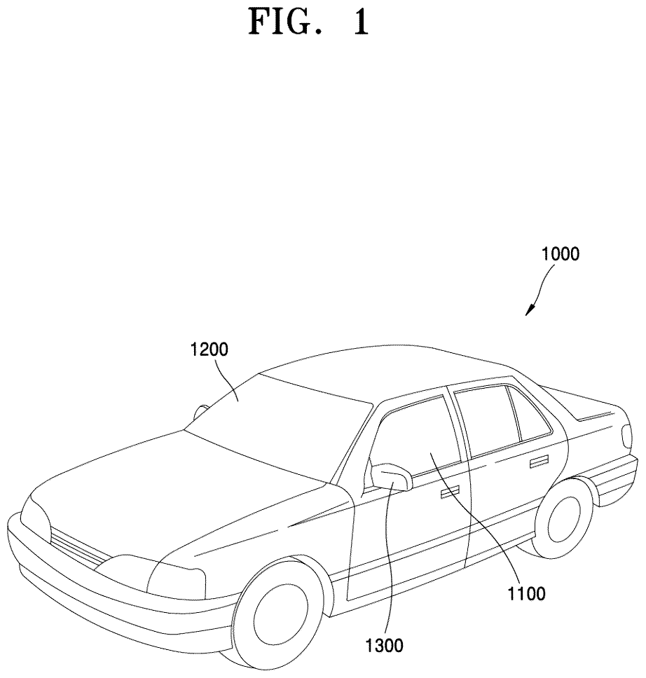

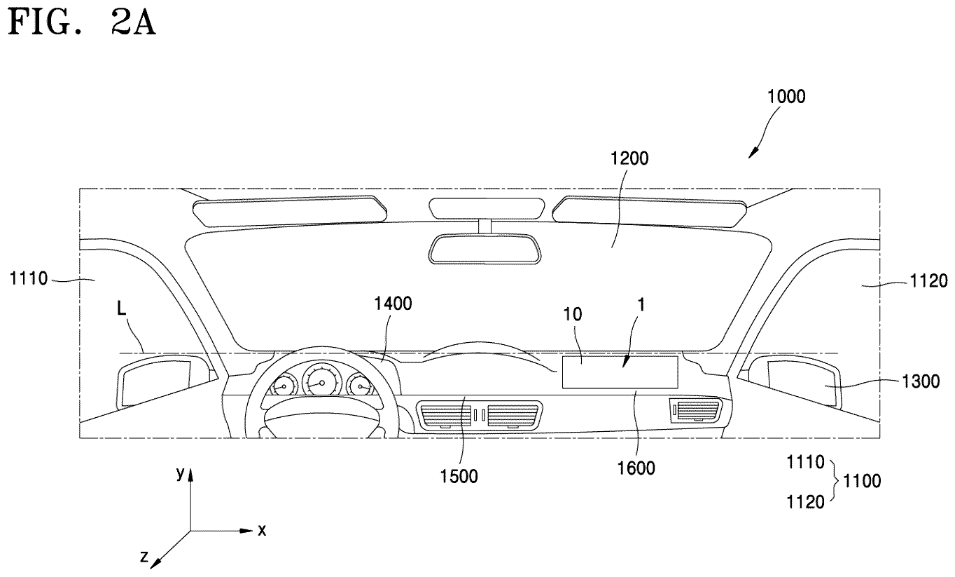

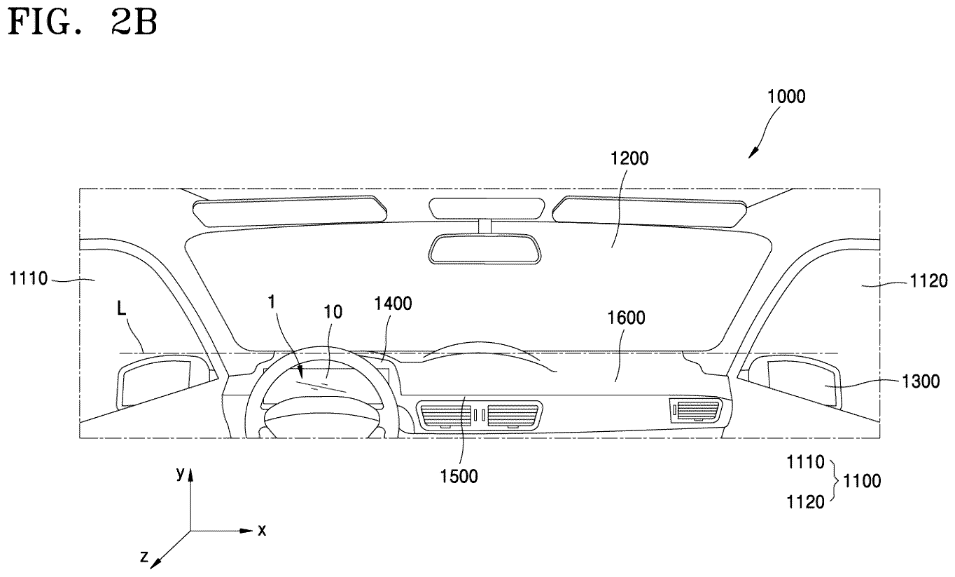

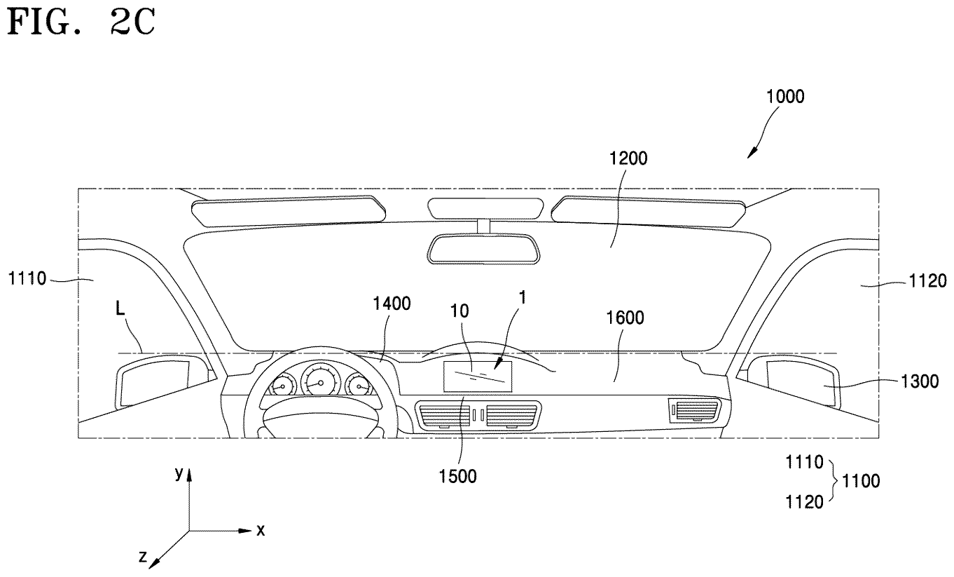

FIG. 1 schematically shows the exterior of a vehicle, according to some embodiments of the present disclosure. FIGS. 2A to 2C schematically show the interior of a vehicle, according to some embodiments of the present disclosure.

Referring to FIGS. 1, 2A, 2B, and 2C, a vehicle 1000 may refer to various devices or living being for moving a transport target object, for example, a human, a product, or an animal, from a departure point to a destination. The vehicle 1000 may include a car driving on a road or track, a vessel moving over the sea or a river, an airplane flying through the air using the action of air, or the like.

In some examples, the vehicle 1000 may navigate a road or a track. The vehicle 1000 may move in a direction according to the rotation of at least one wheel. For example, the vehicle 1000 may include three-wheeled or four-wheeled cars, construction machinery, two-wheeled motor vehicles, motorized devices, bicycles, trains running on tracks, or the like.

The vehicle 1000 may include a body having an interior and exterior and a chassis, which is the remaining portion of the vehicle 1000 other than the body and includes mechanical devices utilized in driving. The exterior of the body may include a front panel, a bonnet, a roof panel, a rear panel, a trunk, pillars on the boundary between doors, and/or the like. The chassis of the vehicle 1000 may include a power generation system, a power transmission system, a running gear, a steering system, a braking system, a suspension system, a transmission system, a fuel system, front, rear, left, and right wheels, and/or the like.

The vehicle 1000 may include a side window glass 1100, a front window glass 1200, a side-view mirrors 1300, a cluster 1400, a center fascia 1500, a passenger side dashboard 1600, and a display apparatus 1.

The side window glass 1100 and the front window glass 1200 may be partitioned by pillars arranged therebetween.

The side window glass 1100 may be installed on the side of the vehicle 1000. In some embodiments, the side window glass 1100 may be installed on a door of the vehicle 1000. A plurality of side window glasses 1100 may be provided and face each other. In some embodiments, the side window glasses 1100 may include first side window glass 1110 and second side window glass 1120. The first side window glass 1110 may be arranged adjacent to the cluster 1400. The second side window glass 1120 may be arranged adjacent to the passenger side dashboard 1600.

The side window glasses 1100 may be spaced apart from each other in a first direction (e.g., −x direction) or in a third direction (e.g., +x direction) opposite to the first direction. For example, the first side window glass 1110 may be spaced apart from the second side window glass 1120 in the x direction or the −x direction. In other words, a virtual line L connecting the side window glasses 1100 may extend in the first direction (e.g., −x direction) or in the third direction (e.g., +x direction). For example, the virtual line L connecting the first side window glass 1110 to the second side window glass 1120 may extend either in the x direction or the −x direction.

The front window glass 1200 may be installed at the front of the vehicle 1000. The front window glass 1200 may be arranged between the side window glasses 1100 facing each other.

The side-view mirror 1300 may provide a view of the rear of the vehicle 1000. The side-view mirror 1300 may be installed on the exterior of the body. In some embodiments, a plurality of side-view mirrors 1300 may be provided. Any one of the side-view mirrors 1300 may be arranged on the outer side of the first side window glass 1110. Another of the side-view mirrors 1300 may be arranged on the outer side of the second side window glass 1120.

The cluster 1400 may be at the front of the steering wheel. On the cluster 1400, a tachometer, a speedometer, a coolant temperature gauge, a fuel gauge, a turn signal indicator, a high beam indicator, warning lights, a seatbelt warning light, a trip meter, an odometer, an automatic transmission selector indicator, a door ajar warning light, an engine oil warning light, and/or a low fuel warning light may be arranged.

The center fascia 1500 may include a control panel with a plurality of buttons for adjusting an audio system, an air conditioning system, and seat heaters. The center fascia 1500 may be on a side of the cluster 1400.

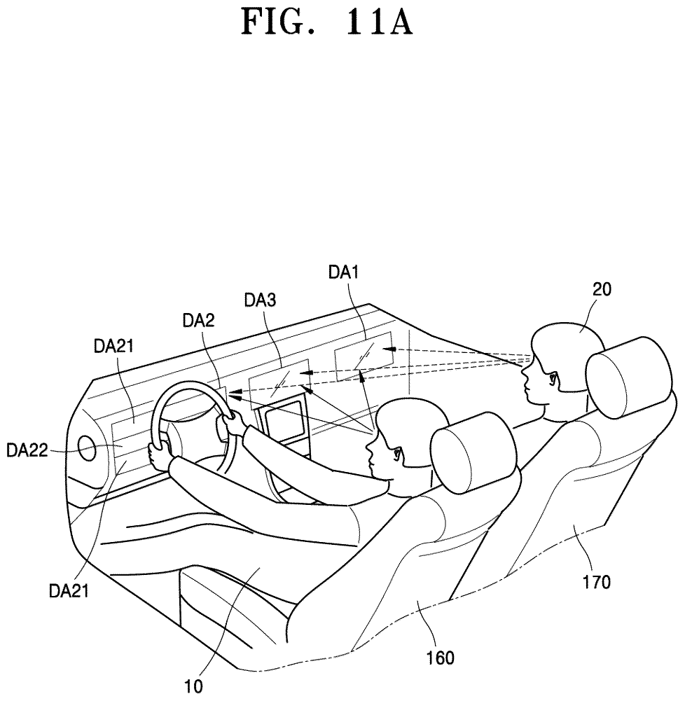

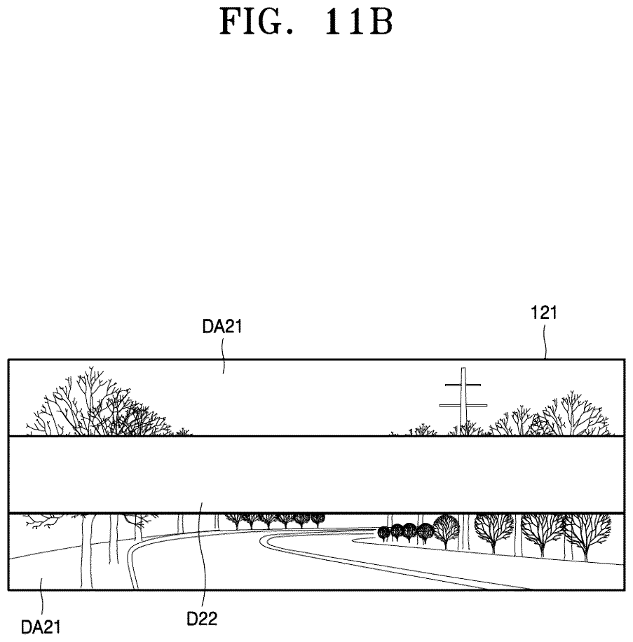

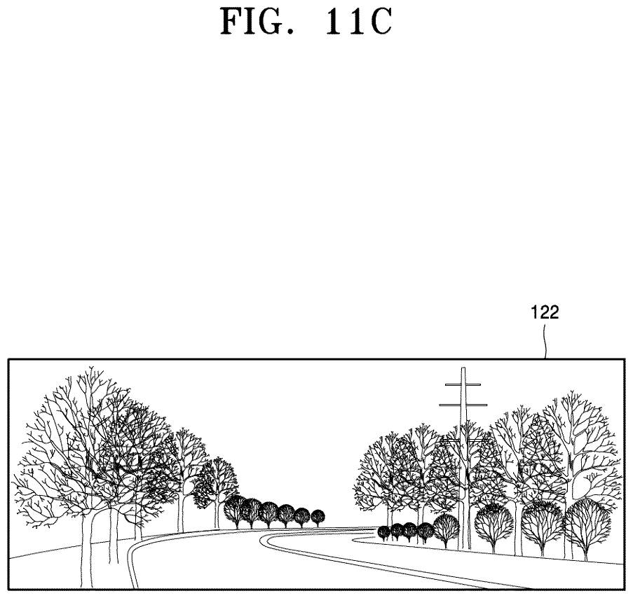

The passenger side dashboard 1600 may be apart from the cluster 1400 with the center fascia 1500 therebetween. In some embodiments, the cluster 1400 may correspond to the driver's seat (160, see, e.g., FIG. 11A), and the passenger side dashboard 1600 may correspond to the passenger seat (170, see, e.g., FIG. 11A). In some embodiments, the cluster 1400 may be adjacent to the first side window glass 1110, and the passenger side dashboard 1600 may be adjacent to the second side window glass 1120.

The display apparatus 1 may be inside the vehicle 1000. The display apparatus 1 may be arranged between the side window glasses 1100 facing each other. The display apparatus 1 may display images. The display apparatus 1 may be arranged on at least any one of the cluster 1400, the center fascia 1500, and the passenger side dashboard 1600.

The display apparatus 1 may include a liquid crystal display apparatus, an electrophoretic display apparatus, an organic light-emitting display apparatus, an inorganic light-emitting display apparatus, a field emission display apparatus, a surface-conduction electron-emitter display apparatus, a quantum dot display apparatus, a plasma display apparatus, a cathode ray display apparatus, and/or the like. Hereinafter, a case where the display apparatus 1 according to some embodiments is an organic light-emitting display apparatus is described, but display apparatuses of various types as stated above may be used in embodiments of the disclosure.

Referring to FIG. 2A, the display apparatus 1 may be arranged on the passenger side dashboard 1600. The display apparatus 1 may be embedded in or installed on the passenger side dashboard 1600. The display apparatus 1 arranged on the passenger side dashboard 1600 may display images regarding the information shown on the cluster 1400 and/or the information shown on the center fascia 1500. In some examples, the display apparatus 1 arranged on the passenger side dashboard 1600 may display information different from the information shown on the cluster 1400 and/or the information shown on the center fascia 1500.

In some embodiments, light emitted from the display apparatus 1 may travel in a specific direction. For example, the light from the display apparatus 1 may travel towards the passenger seat (170, see, e.g., FIG. 11A). Part of the light from the display apparatus 1 may travel towards the driver's seat (160, see, e.g., FIG. 11A), while another part thereof may not travel towards the driver's seat (160, see, e.g., FIG. 11A). The light from the display apparatus 1 may travel towards the front window glass 1200. The light from the display apparatus 1 may travel towards the second side window glass 1120. In some embodiments, the light emitted from a certain region of the display area of the display apparatus 1 arranged on the passenger side dashboard 1600 may travel in a specific direction. Therefore, the light traveling towards the driver's seat (160, see, e.g., FIG. 11A) may be reduced.

Referring to FIG. 2B, the display apparatus 1 may be arranged on the cluster 1400. In such examples, the cluster 1400 may display driving information and the like using the display apparatus 1. That is, the cluster 1400 may be implemented in a digital form. The cluster 1400 in the digital form may display vehicle information and driving information as images. For example, the needle and gauge of the tachometer and icons of various warning lights may be displayed using digital signals.

In some embodiments, the light emitted from the display apparatus 1 may travel in a specific direction. For example, the light emitted from the display apparatus 1 may travel towards the driver's seat (160, see, e.g., FIG. 11A). Part of the light from the display apparatus 1 may travel towards the passenger seat (170, see, e.g., FIG. 11A), while another part thereof may not travel towards the passenger seat (170, see, e.g., FIG. 11A). The light from the display apparatus 1 may travel towards the front window glass 1200. The light from the display apparatus 1 may travel towards the first side window glass 1110. In some embodiments, the light emitted from a certain region of the display area of the display apparatus 1 arranged on the cluster 1400 may travel in a specific direction. Therefore, the light traveling towards the passenger seat (170, see, e.g., FIG. 11A) may be reduced.

Referring to FIG. 2C, the display apparatus 1 may be arranged on the center fascia 1500. The display apparatus 1 may display navigation information. The display apparatus 1 may display information regarding audio, video, vehicle settings, and/or the like.

In some embodiments, the light emitted from the display apparatus 1 may travel in all directions. The light from the display apparatus 1 may travel towards the driver's seat (160, see, e.g., FIG. 11A). The light from the display apparatus 1 may travel towards the passenger seat (170, see, e.g., FIG. 11A). The light from the display apparatus 1 may travel towards the front window glass 1200.

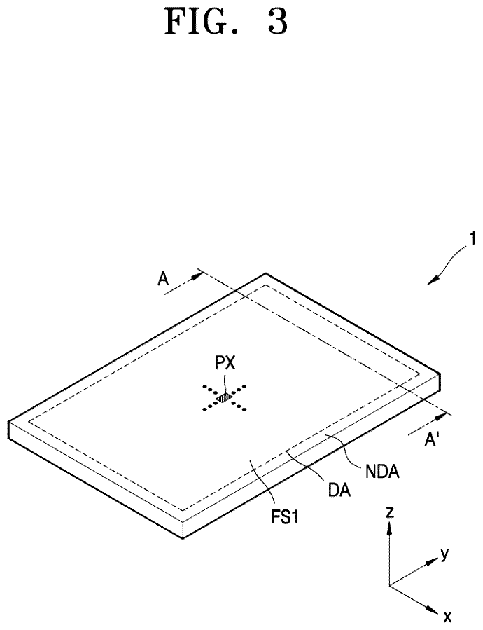

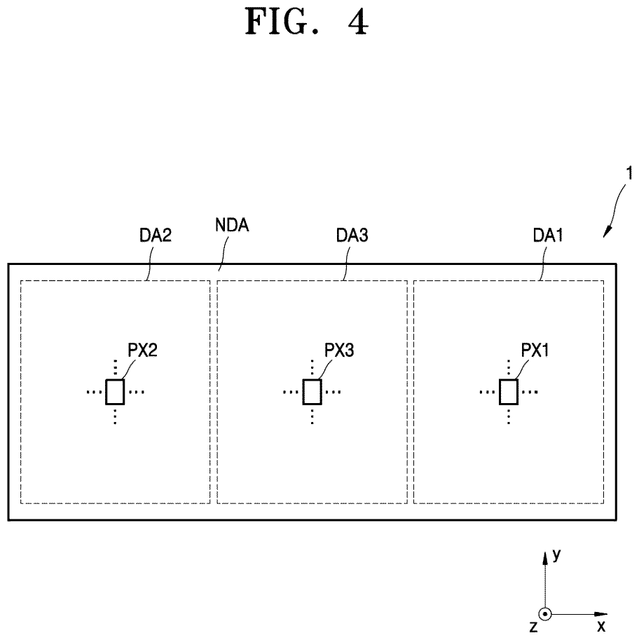

FIG. 3 is a schematic perspective view of a display apparatus according to some embodiments of the present disclosure. FIG. 4 is a schematic plan view of the display apparatus according to some embodiments of the present disclosure.

Referring to FIG. 3, the display apparatus 1 may include a display area DA and a non-display area NDA. In the display area DA, pixels PX may be arranged. In some embodiments, the pixel PX may be on a front surface FS1 of the display apparatus 1.

The pixels PX may be in the display area DA. The pixel PX may be realized as a light-emitting element. The light emitted from the pixel PX may move from the front surface FS1 of the display apparatus 1 in a specific direction. The light emitted from the pixel PX may not move from the front surface FS1 of the display apparatus 1 in another specific direction. In some embodiments, the light emitted from the pixel PX may travel in a direction perpendicular to the front surface FS1 of the display apparatus 1 (e.g., the z direction). The light from the pixel PX may travel in a direction that is oblique to the front surface FS1 of the display apparatus 1 (e.g., the direction crossing the z direction). In some embodiments, the light emitted from the pixel PX may not have a component in at least one of the first direction (e.g., −x direction) and a second direction (e.g., +y direction) crossing the first direction.

The pixel PX may emit red light, green light, or blue light using the light-emitting element. In some embodiments, the pixel PX may emit red light, green light, blue light, or white light using the light-emitting element. The pixel PX may be defined as an emission area of the light-emitting element emitting any one of red light, green light, blue light, and white light.

The pixel PX may include a light-emitting diode capable of emitting light of a certain color as a light-emitting element. In some embodiments, the light-emitting diode may include, as an emission layer, an organic light-emitting diode including an organic material. In some other embodiments, the light-emitting diode may include an inorganic light-emitting diode. In some other embodiments, the light-emitting diode may include a quantum dot as an emission layer. The size of the light-emitting diode may be on a micro-scale or a nanoscale. For example, the light-emitting diode LED may be a micro-light-emitting diode. In some examples, the light-emitting diode may be a nano light-emitting diode. The nano light-emitting diode may include gallium nitride (GaN). Hereinafter, for convenience, examples in which the light-emitting diode includes an organic light-emitting diode is described in further detail.

The non-display area NDA may be an area where no images are provided. The non-display area NDA may surround at least a portion of the display area DA. In some embodiments, the non-display area NDA may entirely surround the display area DA. In some embodiments, drivers or the like configured to provide electrical signals or power to the pixel PX may be arranged in the non-display area NDA. In addition, the non-display area NDA may include a pad area including a pad.

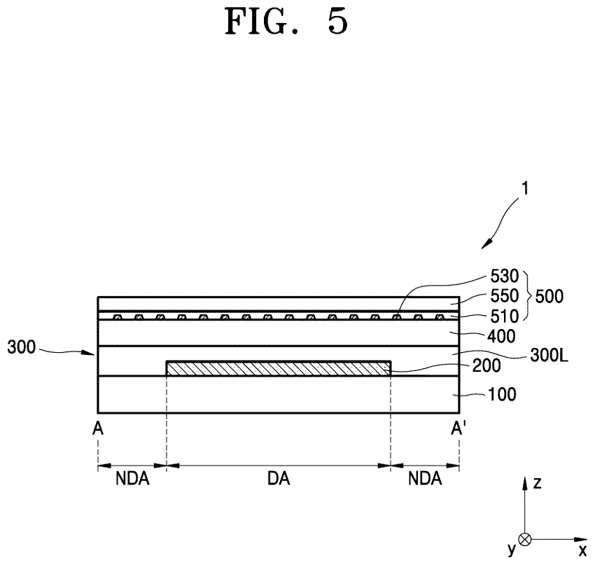

Referring to FIG. 4, the display apparatus 1 may include the display area DA and the non-display area NDA. The display apparatus 1 may include a substrate (100, see, e.g., FIG. 5) and a multilayer film on the substrate (100, see, e.g., FIG. 5). The display area DA and the non-display area NDA may be defined on the substrate (100, see, e.g., FIG. 5) and/or the multilayer film. For example, the display area DA and the non-display area NDA may be defined on the substrate (100, see, e.g., FIG. 5). In other words, the substrate (100, see, e.g., FIG. 5) may include the display area DA and the non-display area NDA. The display area DA may include a first display area DA1, a second display area DA2, and a third display area DA3. In the present specification, a part of the display apparatus 1 that corresponds to the first display area DA1 may be a first display unit, a part of the display apparatus 1 that corresponds to the second display area DA2 may be a second display unit, and a part of the display apparatus 1 that corresponds to the third display area DA3 may be a third display unit.

In the display area DA, a plurality of pixels PX1, PX2, and PX3 may be arranged. The plurality of pixels PX1, PX2, and PX3 may display images. Pixels in the first display area DA1 may be first pixels PX1, pixels in the second display area DA2 may be second pixels PX2, and pixels in the third display area DA3 may be third pixels PX3.

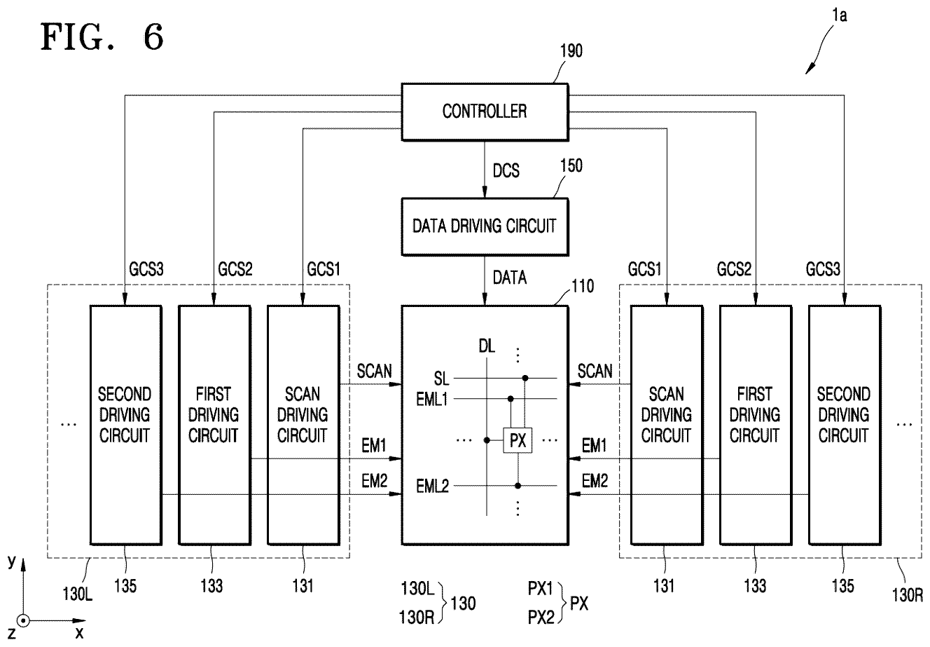

The non-display area NDA may be outside the display area DA. The non-display area NDA may surround at least a portion of the display area DA. In some embodiments, the non-display area NDA may entirely surround the display area DA. In the non-display area NDA, gate driver circuits (130, see, e.g., FIG. 6) configured to respectively provide gate signals to the pixels PX1, PX2, and PX3 may be arranged. In the non-display area NDA, a data driving circuit (150, see, e.g., FIG. 6) configured to provide data signals to the pixels PX1, PX2, and PX3 may be arranged. The non-display area NDA may include a pad area. In the pad area, a pad may be arranged. The pad may be exposed without being covered by an insulating layer and may be electrically connected to a printed circuit board or a driver integrated circuit (IC). Signals and/or voltages transmitted from the printed circuit board or the driver IC through the pad may be respectively delivered to the pixels PX1, PX2, and PX3 arranged in the display area DA through wires connected to the pad.

FIG. 5 is a schematic cross-sectional view of the display apparatus 1 of FIG. 3, taken along the line A-A′ of FIG. 3, according to some embodiments of the present disclosure.

Referring to FIG. 5, the display apparatus 1 may include a substrate 100, a display layer 200, an encapsulation member 300, an anti-reflection layer 400, and an optical path control layer 500. The substrate 100 may include glass or polymer resin, such as polyethersulfone, polyarylate, polyetherimide, polyethylene naphthalate, polyethylene terephthalate, polyphenylene sulfide, polyimide, polycarbonate, cellulose triacetate, or cellulose acetate propionate. The substrate 100 may have a multilayered structure that includes a base layer including the above polymer resin and a barrier layer. The substrate 100 including polymer resin may be flexible, rollable, or bendable.

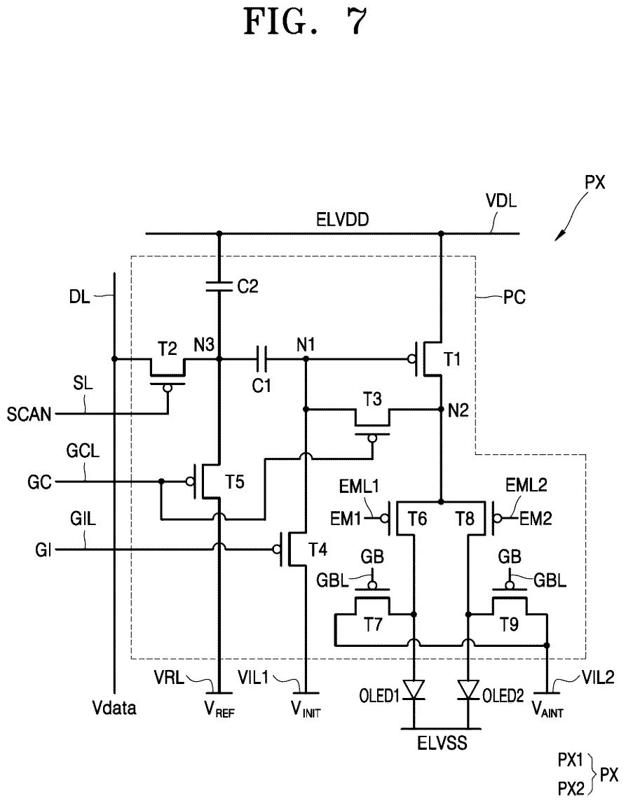

The display layer 200 may be disposed over the substrate 100. The display layer 200 may include a pixel circuit layer and a light-emitting element layer. The pixel circuit layer may include a pixel circuit (PC, see, e.g., FIG. 7). The pixel circuit (PC, see, e.g., FIG. 7) may include a transistor and a storage capacitor. The light-emitting element layer may include light-emitting elements (OLED1 and OLED2, see, e.g., FIG. 7) connected to the pixel circuit (PC, see, e.g., FIG. 7).

The encapsulation member 300 may include an encapsulation layer 300L. The encapsulation layer 300L may include at least one inorganic encapsulation layer and at least one organic encapsulation layer. At least one inorganic encapsulation layer and at least one organic encapsulation layer may be alternately stacked. At least one inorganic encapsulation layer may include one or more inorganic materials including aluminum oxide (Al₂O₃), titanium oxide (TiO₂), tantalum oxide (Ta₂O₅), zinc oxide (ZnOₓ), silicon oxide (SiO₂), silicon nitride (SiNₓ), and silicon oxynitride (SiON). ZnOₓ may include zinc oxide (ZnO) and/or zinc peroxide (ZnO₂). At least one organic encapsulation layer may include a polymer-based material. The polymer-based material may include acrylic resin, epoxy-based resin, polyimide, polyethylene, and the like. In some embodiments, at least one organic encapsulation layer may include acrylate.

The anti-reflection layer 400 may be disposed over the encapsulation member 300. The anti-reflection layer 400 may reduce the reflectivity of light (e.g., external light) that is incident towards the display apparatus 1 from the outside. In some embodiments, the anti-reflection layer 400 may include a retarder and/or a polarizer. The retarder may be of a film type or a liquid crystal coating type and may include a half-wavelength (λ/2) retarder and/or a a quarter-wavelength (λ/4) retarder. The polarizer may also be of a film type or a liquid crystal coating type. The film type may include a stretched synthetic resin film, and the liquid crystal coating type may include liquid crystals arranged in a certain arrangement. The retarder and the polarizer may further include a protective film.

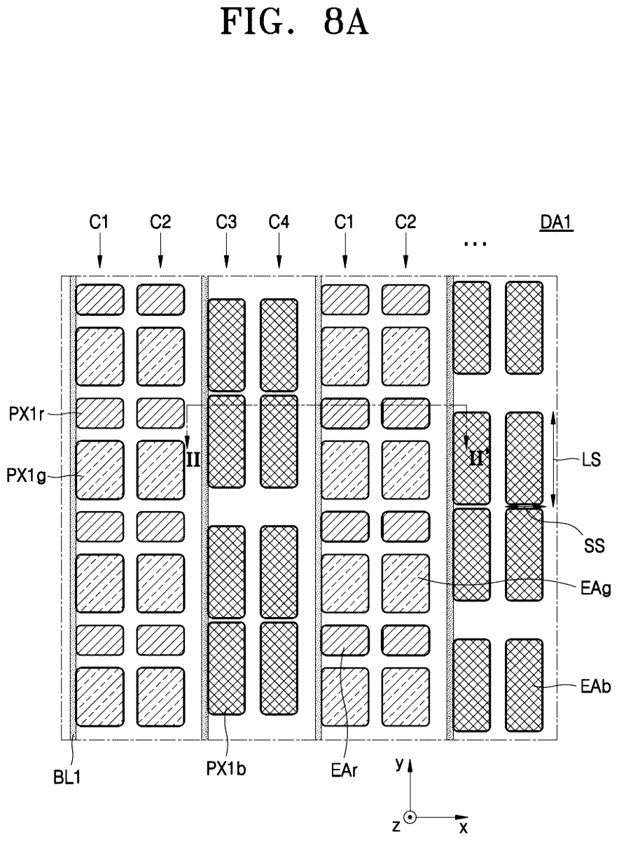

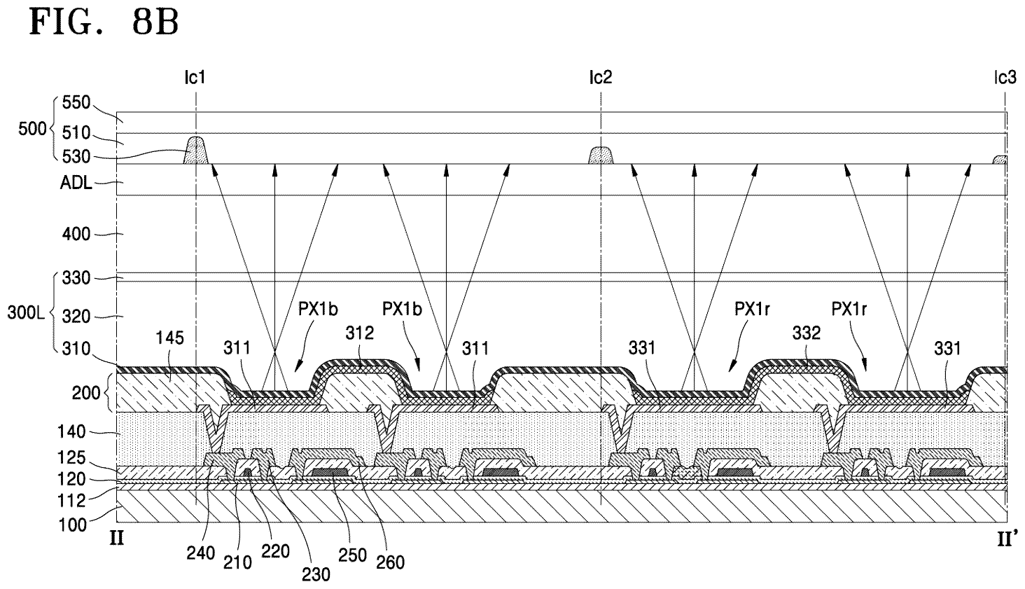

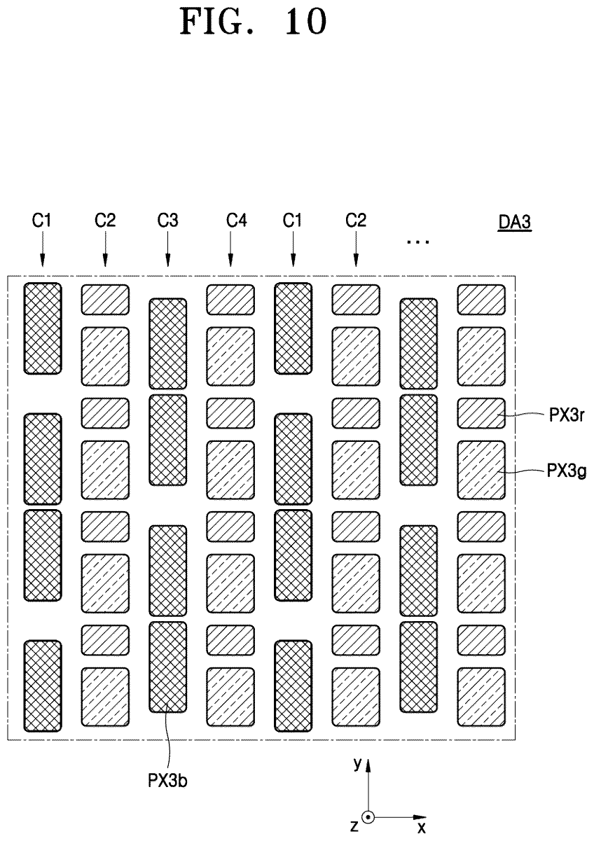

The optical path control layer 500 may be disposed over the anti-reflection layer 400. In some embodiments, an adhesive layer (ADL, see, e.g., FIGS. 8B and 10B) may be arranged between the optical path control layer 500 and the anti-reflection layer 400. The optical path control layer 500 may control the direction of the light emitted from the display layer 200. For example, the portions of the light emitted from the display layer 200 in the first direction (e.g., the −x direction) may be at least partially removed by the optical path control layer 500. The optical path control layer 500 may include a first layer 510, a plurality of light-blocking lines 530, and a second layer 550. The first layer 510 may include transparent resin. In some embodiments, the first layer 510 may include a plurality of grooves. The plurality of grooves may be arranged at regular intervals.

The plurality of light-blocking lines 530 may fill the plurality of grooves. The plurality of light-blocking lines 530 may include light-blocking materials. For example, the plurality of light-blocking lines 530 may include black materials. The plurality of light-blocking lines 530 may be formed by filling the plurality of grooves with black ink and then irradiating ultraviolet rays thereon. The plurality of light-blocking lines 530 may extend in the second direction (e.g., the +y direction). The plurality of light-blocking lines 530 may be spaced apart from each other in the first direction (e.g., the −x direction) or in the third direction (e.g., the +x direction) that is crossing or orthogonal to the second direction (e.g., the +y direction).

The second layer 550 may be arranged on the first layer 510 and the plurality of light-blocking lines 530. The second layer 550 may include polymer resin. For example, the second layer 550 may include polycarbonate.

FIG. 6 schematically shows a display apparatus according to some embodiments of the present disclosure.

A display apparatus 1a of FIG. 6 may be substantially similar to the display apparatus 1 of FIG. 3 or FIG. 4. As shown in FIG. 6, the display apparatus 1a may include a pixel unit 110, a gate driving circuit 130, a data driving circuit 150, and a controller 190.

The pixel unit 110 may represent the first display area (DA1, see, e.g., FIG. 4) and/or the second display area (DA2, see, e.g., FIG. 4). In some embodiments, in the non-display area NDA, various conductive lines configured to transmit electrical signals to the display area DA, outer circuits electrically connected to pixel circuits, and pads to which a printed circuit board or a driver IC chip is attached may be located. For example, in the non-display area NDA, the gate driving circuit 130, the data driving circuit 150, a power supply circuit, and the controller 190 may be arranged.

In the pixel unit 110, a plurality of gate lines may be arranged apart from each other at regular intervals in a y direction (e.g., a column direction). The gate lines may each extend in an x direction (e.g., a row direction) and may be connected to the pixels PX located in the same row (a row line). For example, the gate lines may include scan lines SL, first gate lines EML1, and second gate lines EML2, and the scan lines SL, the first gate lines EML1, and the second gate lines EML2 may be arranged in respective rows.

In the pixel unit 110, data lines DL may be arranged apart from each other at regular intervals in the x direction. The data lines DL may respectively extend in the y direction and may be connected to the pixels PX located in the same column (in the same column line).

The gate driving circuit 130 may be connected to gate lines and is configured to apply gate signals to the gate lines. The gate line may be connected to a gate of a transistor included in the pixel PX. The gate signal may be a gate control signal configured to control the turning on and off of the transistor. The gate signal may be a square wave signal that includes a gate-on voltage, at which a transistor may be turned on, and a gate-off voltage, at which the transistor may be turned off. In some embodiments, the gate-on voltage may be a low-level voltage (a first-level voltage) or a high-level voltage (a second-level voltage).

The gate driving circuit 130 may include a first gate driving circuit unit 130L positioned on a side of the pixel unit 110 in the first direction (−x direction) and a second gate driving circuit unit 130R positioned on a side of the pixel unit 110 in the third direction (+x direction). In some embodiments, the first gate driving circuit unit 130L may include a scan driving circuit 131, a first driving circuit 133, and a second driving circuit 135, and the second gate driving circuit unit 130R may include a scan driving circuit 131, a first driving circuit 133, and a second driving circuit 135. Each of the first gate driving circuit unit 130L and the second gate driving circuit unit 130R may further include at least one gate driving circuit to apply gate signals (GI, GC, and GB, see, e.g., FIG. 7) to the gate of the transistor included in the pixel PX. FIG. 6 shows that the gate driving circuit 130 is arranged on each of the left side and the right side of the pixel unit 110, but one or more embodiments are not limited thereto. The gate driving circuit 130 may be arranged on one side including the left side or the right side of the pixel unit 110.

The scan driving circuits 131 may be electrically connected to the scan lines SL and is configured to provide a first gate signal SCAN to the first gate lines SL according to a first control signal GCS1. The first driving circuits 133 may be electrically connected to the first gate lines EML1 and is configured to provide a first gate signal EM1 to the first gate lines EML1 according to a second control signal GCS2. The second driving circuits 135 may be connected to the second gate lines EML2 and is configured to provide a second gate signal EM2 to the second gate lines EML2 according to a third control signal GCS3. In some embodiments, the gate driving circuit 130 may be configured to provide gate signals to the pixels PX of the pixel unit 110 through the gate lines. The gate driving circuit 130 may be configured to provide gate signals from the pixels PX to selected lines among the gate lines. In other words, the gate driving circuit 130 may be a driving circuit of a decoder type that includes a plurality of decoder stages. In some embodiments, the gate driving circuit 130 may receive a plurality of input selection signals, select one of the gate lines based on levels of turn-on voltages of the received input selection signals, and output a gate signal corresponding to the selected gate line. Therefore, the display apparatus 1 may include a gate driving circuit 130 of a decoder type to individually provide gate signals to the pixels PX in a specific region of the pixel unit 110.

The data driving circuit 150 may be connected to the data lines DL and is configured to apply a data signal DATA, which represents a grayscale, to the data lines DL according to a data control signal DCS. The data driving circuit 150 may convert input image data with a grayscale, which is input from the controller 190, into a data signal DATA in the form of voltage or current.

The power supply circuit may generate voltages utilized for the operations of the pixels PX, according to a power supply control signal (PCS). For example, the power supply circuit may generate a first driving voltage (ELVDD) and a second driving voltage (ELVSS) and provide the same to the pixels PX. The first driving voltage ELVDD may be a high-level voltage provided to an electrode of a driving transistor connected to a first electrode (e.g., a pixel electrode or an anode) of a display element included in the pixel PX. The second driving voltage ELVSS may be a low-level voltage provided to a second electrode (e.g., an opposite electrode or a cathode) of a display element included in the pixel PX. The power supply circuit may generate a first initialization voltage (VINT, see, e.g., FIG. 7) and a second initialization voltage (VAINT, see, e.g., FIG. 7) and provide the same to the pixels PX. The voltage level of the first driving voltage ELVDD may be higher than that of the second driving voltage ELVSS. The voltage levels of the first initialization voltage VINT and the second initialization voltage VAINT may be lower than that of the second driving voltage ELVSS. In addition, the power supply circuit may generate a high-level voltage and a low-level voltage utilized in the operation of the gate driving circuit 130 and may transmit the high-level voltage and the low-level voltage to the gate driving circuit 130.

The controller 190 may generate control signals GCS1, GCS2, GCS3, DCS1, DCS2, DCS3, and PCS based on signals that are input from the outside and may provide the same to the gate driving circuit 130, the data driving circuit 150, and the power supply circuit. Each of the control signals GCS1, GCS2, and GCS3 that are output to the gate driving circuit 130 may include a plurality of clock signals and a gate start signal. The data control signal DCS that is output to the data driving circuit 150 may include a data start signal and clock signals.

FIG. 7 is an equivalent circuit diagram of a pixel circuit according to some embodiments of the present disclosure.

Referring to FIG. 7, the pixel PX may include a pixel circuit PC and display elements, for example, a first organic light-emitting diode OLED1 and a second organic light-emitting diode OLED2, which are connected to the pixel circuit PC. The first organic light-emitting diode OLED1 may emit light as the second gate signal EM1 is provided to the pixel circuit PC from the second driving circuit (135, see, e.g., FIG. 6), and the second organic light-emitting diode OLED2 may emit light as the third gate signal EM2 is provided to the pixel circuit PC from the third driving circuit (150, see, e.g., FIG. 6).

The pixel circuit PC of the pixel PX may include a first transistor T1 to a ninth transistor T9, a first capacitor C1, a second capacitor C2, and signal lines connected thereto. The signal lines may include a data line DL, a first gate line SL, a second gate line EML1, a third gate line EML2, a fourth gate line GIL, a fifth gate line GCL, a sixth gate line GBL, a driving voltage line VDL, a reference voltage line VRL, a first initialization voltage line VIL1, and a second initialization voltage line VIL2.

The first transistor T1 may be a driving transistor in which the intensity of a source-drain current is determined according to a gate-source voltage, and the second transistor T2 to the ninth transistor T9 may each be a switching transistor that is turned on/off according to the gate-source voltage, substantially, a gate voltage. The first transistor T1 to the ninth transistor T9 may be realized as thin-film transistors. Depending on the type (e.g., a p-type or n-type) and/or operation conditions of the transistor, a first terminal of each of the first transistor T1 to the ninth transistor T9 may be a source or a drain, and a second terminal thereof may be different from the first terminal. For example, when the first terminal is a source, the second terminal may be a drain.

The first transistor T1 to the ninth transistor T9 may each be a p-type silicon thin-film transistor. A gate-on voltage of a gate signal for turning on the first transistor T1 to the ninth transistor T9 may be a low-level voltage (i.e., a second-level voltage), and a gate-off voltage of a gate signal for turning off the first transistor T1 to the ninth transistor T9 may be a high-level voltage (i.e., a first-level voltage).

The first transistor T1 may be connected between the driving voltage line VDL and the first organic light-emitting diode OLED1 and the second organic light-emitting diode OLED2. The first transistor T1 may be connected to the driving voltage line VDL and electrically connected to the first organic light-emitting diode OLED1 through the sixth transistor T6. In addition, the first transistor T1 may be electrically connected to the second organic light-emitting diode OLED2 through the eighth transistor T8. The first transistor T1 includes a gate connected to a first node N1, a first terminal connected to the driving voltage line VDL, and a second terminal connected to a second node N2. The first transistor T1 may supply a driving current, which corresponds to a voltage applied to the first node N1, to the first organic light-emitting diode OLED1 and the second organic light-emitting diode OLED2, according to a switching operation of the second transistor T2.

The second transistor T2 may be connected between the data line DL and a third node N3. The second transistor T2 may include a gate connected to the first gate line SL, a first terminal connected to the data line DL, and a second terminal connected to the third node N3. The second transistor T2 may be turned on in response to a first gate signal SCAN transmitted through the first gate line SL, and is configured to transmit a data signal Vdata, which is transmitted through the data line DL, to the third node N3.

The third transistor T3 may be connected between the first node N1 and the second node N2. The third transistor T3 may be connected to the first organic light-emitting diode OLED1 through the sixth transistor T6. In addition, the third transistor T3 may be connected to the second organic light-emitting diode OLED2 through the eighth transistor T8. The third transistor T3 may include a gate connected to the fifth gate line GCL, a first terminal connected to the second node N2, and a second terminal connected to the first node N1. The third transistor T3 may be turned on in response to the third gate signal GC transmitted through the fifth gate line GCL and may be diode-connected to the first transistor T1. When the first transistor T1 is diode-connected, a threshold voltage of the first transistor T1 may be compensated for.

The fourth transistor T4 may be connected between the first node N1 and the first initialization voltage line VIL1. The fourth transistor T4 may include a gate connected to the fourth gate line GIL, a first terminal connected to the first node N1, and a second terminal connected to the first initialization voltage line VIL1. The fourth transistor T4 may be turned on in response to the fourth gate signal GI transmitted through the fourth gate line GIL and may transmit the first initialization voltage VINT to the first node N1, thus initializing the first node N1, that is, the gate of the first transistor T1.

The fifth transistor T5 may be connected between the third node N3 and the reference voltage line VRL. The fifth transistor T5 may include a gate connected to the fifth gate line GCL, a first terminal connected to the third node N3, and a second terminal connected to the reference voltage line VRL. The fifth transistor T5 may be turned on in response to the fifth gate signal GC transmitted through the fifth gate line GCL and may transmit a reference voltage VREF to the third node N3.

The sixth transistor T6 may be connected between the second node N2 and the first organic light-emitting diode OLED1. The sixth transistor T6 may include a gate connected to the second gate line EML1, a first terminal connected to the second node N2, and a second terminal connected to the pixel electrode of the first organic light-emitting diode OLED1. When the sixth transistor T6 is turned on in response to the second gate signal EM1 transmitted through the second gate line EML1, a driving current may flow in the first organic light-emitting diode OLED1.

The seventh transistor T7 may be connected between the first organic light-emitting diode OLED1 and the second initialization voltage line VIL2. The seventh transistor T7 may include a gate connected to the sixth gate line GBL, a first terminal connected to the second terminal of the sixth transistor T6 and the pixel electrode of the first organic light-emitting diode OLED1, and a second terminal connected to the second initialization voltage line VIL2. The seventh transistor T7 may be turned on in response to the sixth gate signal GB transmitted through the sixth gate line GBL, and is configured to transmit the second initialization voltage VAINT to the pixel electrode of the first organic light-emitting diode OLED1, thus initializing the pixel electrode of the first organic light-emitting diode OLED1.

The eighth transistor T8 may be connected between the second node N2 and the second organic light-emitting diode OLED2. The eighth transistor T8 may include a gate connected to the third gate line EML2, a first terminal connected to the second node N2, and a second terminal connected to the pixel electrode of the second organic light-emitting diode OLED2. When the eighth transistor T8 is turned on in response to the third gate signal EM2 transmitted through the third gate line EML2, a driving current may flow in the second organic light-emitting diode OLED2.

The ninth transistor T9 may be connected between the second organic light-emitting diode OLED2 and the second initialization voltage line VIL2. The ninth transistor T9 may include a gate connected to the sixth gate line GBL, a first terminal connected to the second terminal of the eighth transistor T8 and the pixel electrode of the second organic light-emitting diode OLED2, and a second terminal connected to the second initialization voltage line VIL2. The ninth transistor T9 may be turned on in response to the sixth gate signal GB transmitted through the sixth gate line GBL, and is configured to transmit the second initialization voltage VAINT to the pixel electrode of the second organic light-emitting diode OLED2, thus initializing the pixel electrode of the second organic light-emitting diode OLED2.

The first capacitor C1 may be connected between the first node N1 and the third node N3. The first capacitor C1 may store a voltage corresponding to the voltage difference between the first node N1 and the third node N3. The first capacitor C1 may be a storage capacitor. The first capacitor C1 may store a threshold voltage of the first transistor T1 and a data signal Vdata that is input through the second transistor T2.

The second capacitor C2 may be connected between the driving voltage line VDL and the third node N3. The second capacitor C2 may store a voltage corresponding to the voltage difference between the driving voltage line VDL and the third node N3. The second capacitor C2 may maintain the data signal Vdata that is input through the second transistor T2.

The first organic light-emitting diode OLED1 and the second organic light-emitting diode OLED2 may each include a pixel electrode (e.g., an anode) and an opposite electrode (e.g., a cathode) facing the pixel electrode, and the opposite electrode may receive the second driving voltage ELVSS. The first organic light-emitting diode OLED1 and the second organic light-emitting diode OLED2 may receive a driving current corresponding to the data signal Vdata from the first transistor T1 and emit light of a certain color so that images may be displayed.

In some embodiments, a plurality of transistors included in the pixel circuit may all be P-type transistors. In some other embodiments, the plurality of transistors included in the pixel circuit may all be N-type transistors, or some of the transistors may be N-type transistors, while others may be P-type transistors.

The transistor according to some embodiments may be any one of an amorphous-Si thin film transistor (TFT), a low temperature polysilicon (LTPS) TFT, and an oxide TFT. The oxide TFT may include, as a semiconductor layer (an active layer), oxide such as amorphous indium-gallium-zinc-oxide (IGZO), ZnO, or TiO.

FIG. 8A is an enlarged view of a first display area of a display apparatus, according to some embodiments of the present disclosure. FIG. 8B is a schematic cross-sectional view of the display apparatus of FIG. 8A, taken along the line II-II′ of FIG. 8A, according to some embodiments of the present disclosure.

Referring to FIG. 8A, in the first display area DA1 of the display apparatus 1, a first sub-pixel PX1b, a second sub-pixel PX1g, a third sub-pixel PX1r, and a first light-blocking line BL1 may be arranged.

The first sub-pixel PX1b may have a long side LS extending in the second direction (+y direction) and a short side SS extending in the first direction (−x direction). The long side LS may be greater than the short side SS. The long side LS and the short side SS may be edges of the first sub-pixel PX1b. In some embodiments, the first sub-pixel PX1b may have a rectangular shape. In some other embodiments, the first sub-pixel PX1b may have a polygonal shape or a circular shape.

The second direction may be an x direction or a −x direction.

In some embodiments, the first sub-pixel PX1b may be a blue sub-pixel. The first sub-pixel PX1b may emit light in a blue wavelength band.

In some embodiments, the size of the first sub-pixel PX1b may be defined as the size of a first emission area EAb of a blue organic light-emitting diode OLEDb as the first display element. The first emission area EAb may be an area where the blue organic light-emitting diode OLEDb emits light. In such examples, the long side LS and the short side SS of the first sub-pixel PX1b may be the long side LS and the short side SS of the first emission area EAb, respectively. The long side LS and the short side SS may be edges of the first emission area EAb.

The first emission area EAb of the blue organic light-emitting diode OLEDb may emit light in the blue wavelength band.

The second sub-pixel PX1g may be arranged on a side of the long side LS of the first sub-pixel PX1b arranged in an odd column or on the other side of the long side LS of the first sub-pixel PX1b arranged in an even column. The second sub-pixel PX1g may be spaced apart from the first sub-pixel PX1b in the first direction (−x direction) or in the third direction (+x direction). In some embodiments, the second sub-pixel PX1g may be spaced apart from the first sub-pixel PX1b in the x direction or the −x direction. In some embodiments, the second sub-pixel PX1g may have a rectangular shape. In some other embodiments, the second sub-pixel PX1g may have a square shape. In some other embodiments, the second sub-pixel PX1g may have a polygonal shape or a circular shape.

In some embodiments, the second sub-pixel PX1g may be a green sub-pixel. The second sub-pixel PX1g may emit light in a green wavelength band.

In some embodiments, the size of the second sub-pixel PX1g may be defined as the size of a second emission area EAg of a green organic light-emitting diode OLEDg as the second display element. The second emission area EAg may be an area where the green organic light-emitting diode OLEDg emits light.

In some embodiments, the second emission area EAg may be arranged on a side of the long side LS of the first emission area EAb. The second emission area EAg may be spaced apart from the first emission area EAb in the first direction (−x direction) or in the third direction (+x direction). In some embodiments, the second emission area EAg may be spaced apart from the first emission area EAb in the x direction or the −x direction.

The second emission area EAg of the green organic light-emitting diode OLEDg may emit light in the green wavelength band.

The third sub-pixel PX1r may be arranged on a side of the long side LS of the first sub-pixel PX1b arranged in an odd column or on the other side of the long side LS of the first sub-pixel PX1b arranged in an even column. In some embodiments, the third sub-pixel PX1r may be spaced apart from the first sub-pixel PX1b in the first direction (−x direction) or in the third direction (+x direction). For example, the third sub-pixel PX1r may be spaced apart from the first sub-pixel PX1b in the x direction or the −x direction. The third sub-pixel PX1r may be spaced apart from the second sub-pixel PX1g. In some embodiments, the third sub-pixel PX1r may be spaced apart from the second sub-pixel PX1g in the second direction (+y direction). For example, the third sub-pixel PX1r may be spaced apart from the second sub-pixel PX1g in the y direction or the −y direction.

In some embodiments, the third sub-pixel PX1r may have a rectangular shape. In some other embodiments, the third sub-pixel PX1r may have a square shape. In some other embodiments, the third sub-pixel PX1r may have a polygonal shape or a circular shape.

In some embodiments, the third sub-pixel PX1r may be a red sub-pixel. The third sub-pixel PX1r may emit light in a red wavelength band.

In some embodiments, the size of the third sub-pixel PX1r may be defined as the size of a third emission area EAr of a red organic light-emitting diode OLEDr as the third display element. The third emission area EAr may be an area where the red organic light-emitting diode OLEDr emits light.

The third emission area EAr may be arranged on a side of the long side LS of the first emission area EAb. In some embodiments, the third emission area EAr may be spaced apart from the first emission area EAb in the first direction (−x direction) or in the third direction (+x direction). For example, the third emission area EAr may be spaced apart from the first emission area EAb in the x direction or the −x direction. The third emission area EAr may be spaced apart from the second emission area EAg. In some embodiments, the third emission area EAr may be spaced apart from the second emission area EAg in the second direction. For example, the third emission area EAr may be spaced apart from the second emission area EAg in the y direction or the −y direction.

The third emission area EAr of the red organic light-emitting diode OLEDr may emit light in the red wavelength band.

Referring to FIGS. 8A and 8B, the area of each first emission area EAb may be greater than that of each second emission area EAg and that of each third emission area EAr. This is because, when the areas of the emission area EAb, the second emission area EAg, and the third emission area Ear are the same, the emission efficiency of a first emission layer 312 emitting blue light may be lower than that of a third emission layer 332 emitting red light.

In some embodiments, in an entire area of a first column C1 and a second column C2, a pair of second sub-pixels PX1g arranged in the first direction (−x direction) and a pair of third sub-pixels PX1r arranged in the first direction (−x direction) may be alternately arranged in the second direction (+y direction). In a third column C3 adjacent to the second column C2 and in a fourth column C4 adjacent to the third column C3, the plurality of first sub-pixels PX1b may be arranged in the second direction (+y direction). Such arrangements of the first sub-pixel PX1b, the second sub-pixel PX1g, and the third sub-pixel PX1r may be repeated in the first direction and/or the second direction.

In some embodiments, the first sub-pixel PX1b, the second sub-pixel PX1g, and the third sub-pixel PX1r in odd-numbered columns may respectively receive the second gate signals EM1 and thus display images due to the emission of the first organic light-emitting diode (OLED1, see, e.g., FIG. 7), and the first sub-pixel PX1b, the second sub-pixel PX1g, and the third sub-pixel PX1r in even-numbered columns may respectively receive the third gate signals EM2 and thus display images due to the emission of the second organic light-emitting diode (OLED2, see, e.g., FIG. 7).

The first light-blocking line BL1 may extend in the second direction (+y direction). In some examples, a plurality of the first light-blocking lines BL1 may be provided. In some embodiments, the first light-blocking line BL1 may be arranged only on a side of each of pixels in odd-numbered columns in the −x direction, that is, the first light-blocking line BL1 may be arranged only on a first direction side (i.e., a side that is positioned furthest along the first direction) of each of pixels in odd-numbered columns among the pixels in the first display area DA1. Therefore, a relatively low number of first light-blocking lines BL1 may overlap the first sub-pixel PX1b, the second sub-pixel PX1g, and the third sub-pixel PX1r, and the luminance decrease in the first sub-pixel PX1b, the second sub-pixel PX1g, and the third sub-pixel PX1r may be reduced.

When light is emitted from each of the first sub-pixel PX1b, the second sub-pixel PX1g, and the third sub-pixel PX1r, which are aligned in odd-numbered columns, the plurality of first light-blocking lines BL1 may prevent or reduce the propagation of light in a direction to the first light-blocking lines, that is, in the first direction (−x direction). Therefore, the light emitted from each of the first sub-pixel PX1b, the second sub-pixel PX1g, and the third sub-pixel PX1r, which are aligned in the odd-numbered columns, may not travel in a specific direction. For example, portions of the light respectively emitted from the first sub-pixel PX1b, the second sub-pixel PX1g, and the third sub-pixel PX1r, which are aligned in the odd-numbered columns, in the first direction (−x direction) may be removed (e.g., blocked). For example, the first display area DA1 may be positioned on the passenger side dashboard (1600, see, e.g., FIG. 2A), and the light emitted from the pixels in the odd-numbered columns among the pixels PX in the first display area DA1 may not travel in the first direction (−x direction). Therefore, images in the first display area DA1 may not be recognized on the driver's seat (160, see, e.g., FIG. 11A) located in the −x direction of the first display area DA1.

In some embodiments, the first driving circuit (133, see, e.g., FIG. 6) may provide turn-on signals (i.e., activation signals), which are the first gate signals to the first gate lines EML1 connected to pixels in odd-numbered columns among the pixels arranged in the first display area DA1, based on a privacy mode control signal from the controller (190, see, e.g., FIG. 6). In addition, the second driving circuit (135, see, e.g., FIG. 6) may provide turn-off signals (i.e., deactivation signals), which are the second gate signals to the second gate lines EML2 connected to pixels in even-numbered columns among the pixels in the first display area DA1, based on the privacy mode control signal from the controller (190, see, e.g., FIG. 6).

In some embodiments, the first driving circuit (133, see, e.g., FIG. 6) may provide turn-off signals, which are the first gate signals to the first gate lines EML1 connected to pixels in odd-numbered columns among the pixels arranged in the first display area DA1, based on a public mode control signal from the controller (190, see, e.g., FIG. 6). In addition, the second driving circuit (135, see, e.g., FIG. 6) may provide turn-on signals, which are the second gate signals to the second gate lines EML2 connected to pixels in even-numbered columns among the pixels in the first display area DA1, based on the public mode control signal from the controller (190, see, e.g., FIG. 6). As described above with respect to FIG. 6, first driving circuit 133 may be arranged on the first direction (−x direction) side of the first display area DA1 and on a third direction (+x direction) side of the first display area DA1. The first driving circuit 133 on the first direction side of the first display area DA1 may be regarded as a 1^{st}-1^{st} driving circuit, and the first driving circuit 133 on the third direction side of the first display area DA1 may be regarded as a 1^{st}-2^{nd} driving circuit.

Also, in some embodiments, because the plurality of first light-blocking lines BL1 extend in the second direction (+y direction) and are located only on the first direction side of the pixels in odd-numbered columns among the pixels in the first display area DA1, the light emitted from the first display area DA1 may be asymmetrical with respect to the second direction.

FIG. 8B is a schematic cross-sectional view of the display apparatus of FIG. 8A, taken along the line II-II′ of FIG. 8A, according to some embodiments of the present disclosure.

As shown in FIG. 8B, a first pixel electrode 311 and a third pixel electrode 331 are disposed over a planarization layer 140, and a pixel-defining layer 145 is disposed over the first pixel electrode 311 and the third pixel electrode 331. The pixel-defining layer 145 may include openings respectively exposing central portions of the first pixel electrode 311 and the third pixel electrode 331, thus covering edges thereof. Pixels shown in FIG. 8A may correspond to the openings of the pixel-defining layer 145. In other words, portions of the first pixel electrodes 311 that are exposed by the openings of the pixel-defining layer 145 may be referred to as first sub-pixels PX1b, and portions of the third pixel electrodes 331 that are exposed by the openings of the pixel-defining layer 145 may be referred to as third sub-pixels PX1r.

Light emission from such pixels may be controlled by thin-film transistors electrically connected to the pixels. FIG. 8B shows that a thin-film transistor that includes a semiconductor layer 210, a gate electrode 220, a source electrode 230, and a drain electrode 240, and a capacitor, which are arranged in each pixel. The capacitor includes a lower electrode 250 and an upper electrode 260. In addition, FIG. 8B shows that the first pixel electrode 311 and the third pixel electrode 331 are electrically connected to the drain electrode 240 of their corresponding thin-film transistors. However, this is only an example, and various suitable modifications may be made. For example, a thin-film transistor may include any one of the source electrode 230 and the drain electrode 240. In such examples, a source area or a drain area of the semiconductor layer 210 may function as a source electrode or a drain electrode of the thin-film transistor. When a plurality of thin-film transistors are provided, a drain area of a first thin-film transistor may be connected to a source area of a second thin-film transistor. In such examples, the first thin-film transistor may not include a drain electrode, and the second thin-film transistor may not include a source electrode.

The thin-film transistor and other components are disposed over the substrate 100. The substrate 100 may include a glass material, metals, or polymer resin. In some examples, when at least a portion of the display apparatus is bent, it is desirable for the substrate 100 to be flexible or bendable. In such examples, the substrate 100 may include polymer resin such as polyethersulfone, polyacrylate, polyetherimide, polyethylene naphthalate, polyethylene terephthalate, polyphenylene sulfide, polyarylate, polyimide, polycarbonate, or cellulose acetate propionate. Various suitable modifications may be made to the substrate 100, and for example, the substrate 100 may have a multilayered structure that includes two layers including the above polymer resin and a barrier layer including an inorganic material (e.g., SiO₂, SiNₓ, SiON, or the like) and arranged between the two layers.

On the substrate 100, a buffer layer 112 including SiO₂, SiNₓ, or SiON may be disposed. The buffer layer 112 may flatten the upper surface of the substrate 100. The semiconductor layer 210 disposed over the buffer layer 112 may include amorphous silicon or polysilicon. When desired, the semiconductor layer 210 may include an oxide semiconductor material.

A gate insulating layer 120 may cover the semiconductor layer 210 and may be disposed over the substrate 100. The gate insulating layer 120 may include an insulating material. For example, the gate insulating layer 120 may include an inorganic insulating layer such as SiO₂, SiNₓ, SiON, or Al₂O₃.

The gate electrode 220 and/or the lower electrode 250 of the capacitor may be disposed over the gate insulating layer 120. When the gate electrode 220 and the lower electrode 250 are disposed over the gate insulating layer 120, the gate electrode 220 and the lower electrode 250 may have the same layer structure and include the same or substantially the same material. For example, the gate electrode 220 and the lower electrode 250 may each include a two-layer structure of molybdenum (Mo)/aluminum (Al), which includes a layer including Mo and a layer including Al, or a tri-layer structure of Mo/Al/Mo.

An interlayer insulating layer 125 may cover the gate electrode 220 and the lower electrode 250 and may be disposed over the gate insulating layer 120. The interlayer insulating layer 125 may include an insulating material. For example, the interlayer insulating layer 125 may include SiO₂, SiNₓ, SiON, Al₂O₃, or the like.

The source electrode 230, the drain electrode 240, and/or the upper electrode 260 of the capacitor may be disposed over the interlayer insulating layer 125. The source electrode 230, the drain electrode 240, and the upper electrode 260 may have the same layer structure and include the same or substantially the same materials. For example, the source electrode 230, the drain electrode 240, and the upper electrode 260 may include a layer including titanium (Ti) and a layer including Al and thus have a tri-layer structure of Ti/Al/Ti.

The planarization layer 140 may cover the source electrode 230, the drain electrode 240, and the upper electrode 260 and may be disposed over the interlayer insulating layer 125. The planarization layer 140 may include an organic insulating material. For example, the planarization layer 140 may include photoresist, benzocyclobutene (BCB), polyimide, hexamethyldisiloxane (HMDSO), polymethylmethacrylate (PMMA), polystyrene, a polymer derivative having a phenol-based group, an acryl-based polymer, an imide-based polymer, an aryl-ether-based polymer, an amide-based polymer, a fluorine-based polymer, a p-xylene-based polymer, a vinyl alcohol-based polymer, or any blend thereof. For example, the planarization layer 140 may include a polyimide layer with a thickness of about 1.6 μm.

The display layer 200 may be disposed over the planarization layer 140. The display layer 200 may include a pixel electrode, an emission layer, and an opposite electrode. The pixel electrodes of the display layer 200 may be spaced apart from each other, and the opposite electrode may be integrally formed on the display layer 200 as a single body. The emission layer may be patterned to correspond to the pixel electrodes. A first functional layer, such as a hole transport layer (HTL) and/or a hole injection layer (HIL), may be arranged between the pixel electrode and the emission layer, and a second functional layer, such as an electron transport layer (ETL) and/or an electron injection layer (EIL), may be arranged between the emission layer and the opposite electrode. The first functional layer and/or the second functional layer may be integrally formed on the display layer 200 as a single body. In FIG. 8B, the first functional layer, the second functional layer, and the opposite electrode are omitted for convenience.

Referring to FIG. 8B, each of the first sub-pixels PX1b includes the first pixel electrode 311 and a first emission layer 312 arranged on the first pixel electrode 311 and emitting first color light. The first color light may be, for example, blue light. Each of the third sub-pixels PX1r includes the third pixel electrode 331 and a third emission layer 332 disposed over the third pixel electrode 331 and emitting third color light. The third color light may be, for example, red light.

The pixel-defining layer 145 described above may be disposed over the planarization layer 140 to cover the edges of the pixel electrodes. The pixel-defining layer 145 may include one or more organic insulating materials selected from the group consisting of polyimide, polyamide, acryl resin, BCB, and phenol resin and may be formed through a spin coating method or the like.

The pixel electrode disposed over the planarization layer 140 may be a (semi-) light-transmissive electrode or a reflection electrode. For example, the pixel electrode may include a reflection layer including silver (Ag), magnesium (Mg), Al, platinum (Pt), palladium (Pd), gold (Au), nickel (Ni), neodymium (Nd), iridium (Ir), chromium (Cr) or a combination thereof, and a transparent or translucent electrode layer disposed over the reflection layer. The transparent or translucent electrode layer may include at least one material selected from the group consisting of indium tin oxide (ITO), indium zinc oxide (IZO), ZnO (or ZnO₂), indium oxide (In₂O₃), indium gallium oxide (IGO), and aluminum zinc oxide (AZO). For example, the pixel electrode may have a tri-layer structure of ITO/Ag/ITO.

The opposite electrode corresponding to the plurality of pixel electrodes may be a light-transmissive electrode or a reflection electrode. For example, the opposite electrode may be a transparent or translucent electrode and include a metal thin-film having a low work function and including lithium (Li), calcium (Ca), lithium fluoride (LiF), Al, Ag, Mg, and a compound thereof. Also, the opposite electrode may include a transparent or translucent electrode layer on the metal thin-film, and in such examples, the transparent or translucent electrode layer may include at least one selected from the group including ITO, IZO, ZnO (or ZnO₂), In₂O₃, IGO, and AZO. The opposite electrode may be integrally formed over the plurality of pixels as a single body and may be arranged on an upper portion of the emission layer and an upper portion of the pixel-defining layer 145.

The encapsulation member (300, see, e.g., FIG. 5) may be disposed over the display layer 200. The encapsulation member (300, see, e.g., FIG. 5) may include the encapsulation layer 300L. The encapsulation layer 300L may include at least one inorganic encapsulation layer and at least one organic encapsulation layer. FIG. 8B shows that the encapsulation layer 300L includes a first inorganic encapsulation layer 310, an organic encapsulation layer 320, and a second inorganic encapsulation layer 330, which are sequentially stacked.

The anti-reflection layer 400 may be disposed over the encapsulation layer 300L.

The optical path control layer 500 may be disposed over the anti-reflection layer 400.

The adhesive layer ADL may be arranged between the optical path control layer 500 and the anti-reflection layer 400. The adhesive layer ADL may be a colorless adhesive member such as an optically clear adhesive (OCA).

The optical path control layer 500 may include a first layer 510, a plurality of light-blocking lines 530, and a second layer 550. The plurality of light-blocking lines 530 included in the optical path control layer 500 may be an example of the first light-blocking line BL1 in the plan view of FIG. 8A. The first layer 510 may include transparent resin. In some embodiments, the first layer 510 may include a plurality of grooves. The plurality of grooves may be arranged at regular intervals. The plurality of light-blocking lines 530 may fill the plurality of grooves, respectively. The plurality of light-blocking lines 530 may be spaced apart from each other in the x direction. The plurality of light-blocking lines 530 may include light-blocking materials.

In some embodiments, the plurality of light-blocking lines 530 may be spaced apart from each other and respectively positioned on a first line lc1, a second line lc2, and a third line lc3 in the x direction. In the plan view of FIG. 8A, the first line lc1, the second line lc2, and the third line lc3 may represent lines showing, in the cross-sectional view, the locations of the first light-blocking lines BL1 arranged on one side of the pixels in odd-numbered columns in the −x direction among the pixels. Referring to FIG. 8B, the plurality of light-blocking lines 530 positioned on the first line lc1, the second line lc2, and the third line lc3 have heights gradually decreasing in the third direction (+x direction) which is opposite to the first direction (−x direction). For example, considering the viewing angle of the driver in the driver's seat (160, see, e.g., FIG. 11A), the light-blocking line on the first line lc1 that is close to the driver's seat in the first direction (−x direction) of the first display area DA1 may be the highest, the light-blocking line on the second line lc2 may be lower than the light-blocking line on the first line lc1, and the light-blocking line on the third line lc3 may be lower than the light-blocking line on the second line lc2. Accordingly, manufacturing costs of the light-blocking lines may be reduced, compared to the case where all of the plurality of light-blocking lines 530 have the same height.

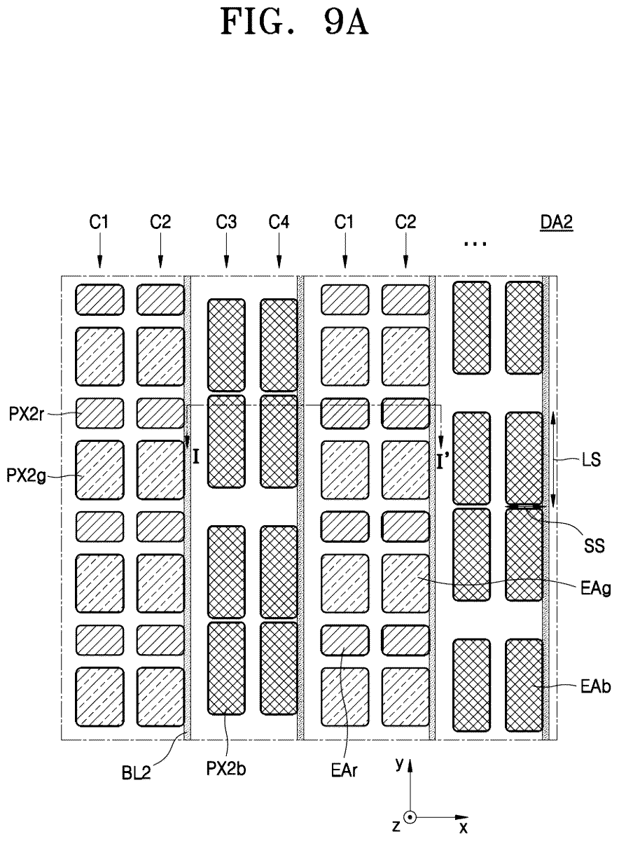

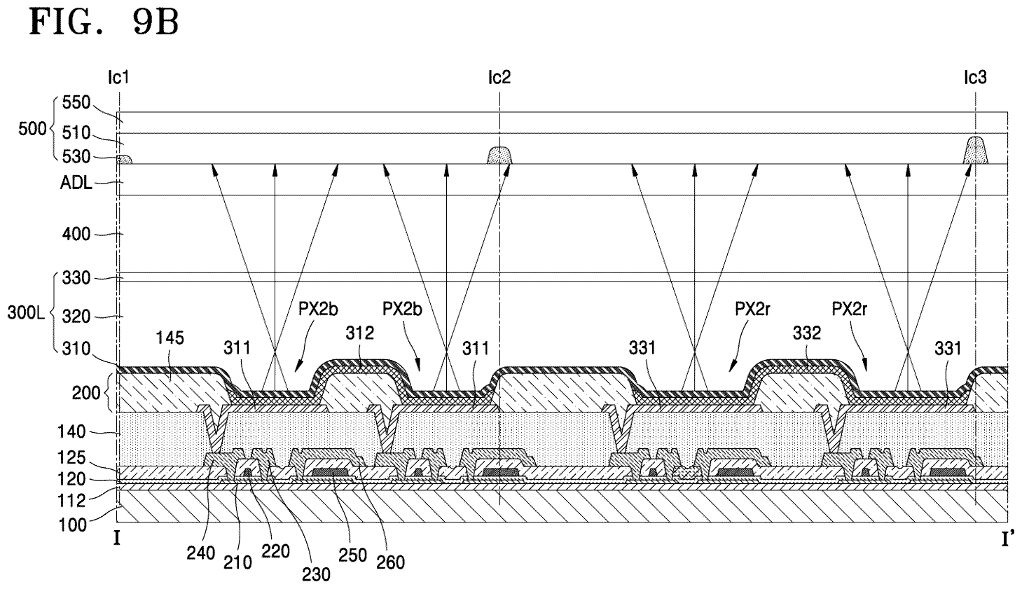

FIG. 9A is an enlarged view of a second display area of a display apparatus, according to some embodiments of the present disclosure. FIG. 9B is a schematic cross-sectional view of the display apparatus of FIG. 9A, taken along the line I-I′ of FIG. 9A, according to some embodiments of the present disclosure.

Because the components shown in FIGS. 9A and 9B mostly overlap those shown in FIGS. 8A and 8B, the differences therebetween are mainly described below.

Referring to FIG. 9A, the second light-blocking line BL2 may extend in the second direction (+y direction). In some examples, a plurality of the second light-blocking line BL2 may be provided. In some embodiments, the second light-blocking line BL2 may be arranged only on one side of each of the pixels in even-numbered columns in the third direction (+x direction) among the pixels in the second display area DA2, that is, the second light-blocking line BL2 may be arranged only on a third direction side (i.e., a side that is positioned furthest along the third direction) of each of the pixels in even-numbered columns among the pixels in the second display area DA2.

When the light is emitted from each of a first sub-pixel PX2b, a second sub-pixel PX2g, and a third sub-pixel PX2r, which are aligned in even-numbered columns, the plurality of second light-blocking lines BL2 may prevent or reduce the propagation of light in the third direction (the +x direction) opposite to the first direction (−x direction). Therefore, the light emitted from each of the first sub-pixel PX2b, the second sub-pixel PX2g, and the third sub-pixel PX2r, which are aligned in the even-numbered columns, may not travel in a specific direction. For example, a third direction component of the light emitted from each of the first sub-pixel PX2b, the second sub-pixel PX2g, and the third sub-pixel PX2r, which are aligned in the even-numbered columns, may be removed (e.g., blocked). For example, the second display area DA2 may be in the cluster (1400, see, e.g., FIG. 2A), and the light emitted from the pixels in the even-numbered columns among the pixels PX included in the second display area DA2 may not travel in the third direction (+x direction). Therefore, images in the second display area DA2 may not be recognized on the passenger seat (170, see, e.g., FIG. 11A) located in the +x direction of the second display area DA2.

In some embodiments, the first driving circuit (133, see, e.g., FIG. 6) may provide turn-off signals (i.e., deactivation signals), which are the first gate signals to the first gate lines EML1 electrically connected to pixels in odd-numbered columns among the pixels arranged in the second display area DA2, based on a privacy mode control signal from the controller (190, see, e.g., FIG. 6). In addition, the second driving circuit (135, see, e.g., FIG. 6) may provide turn-on signals (i.e., activation signals), which are the second gate signals to the second gate lines EML2 electrically connected to pixels in even-numbered columns among the pixels in the second display area DA2, based on the privacy mode control signal from the controller (190, see, e.g., FIG. 6). For convenience of description, the first gate line EML1 electrically connected to the pixels in the odd-numbered columns arranged in the second display area DA2 can be regarded as a third gate line, and the first driving circuit 133 electrically connected to the first gate line EML1 and providing the first gate signals can be regarded as a third driving circuit providing third gate signals. Similarly, the second gate line EML2 electrically connected to the pixels in the even-numbered columns arranged in the second display area DA2 can be regarded as a fourth gate line, and the second driving circuit 135 electrically connected to the second gate line EML2 and providing the second gate signals can be regarded as a fourth driving circuit providing fourth gate signals.

In some embodiments, the first driving circuit (133, see, e.g., FIG. 6), which may be regarded as the third driving circuit, may provide turn-on signals, which are third gate signals, to the first gate lines EML1, which may be regarded as the third gate lines connected to pixels in odd-numbered columns among the pixels arranged in the second display area DA2, based on a public mode control signal from the controller (190, see, e.g., FIG. 6). In addition, the second driving circuit (135, see, e.g., FIG. 6), which may be regarded as the fourth driving circuit, may provide turn-off signals, which are fourth gate signals, to the second gate lines EML2, which may be regarded as the fourth gate lines connected to pixels in even-numbered columns among the pixels in the second display area DA2, based on the public mode control signal from the controller (190, see, e.g., FIG. 6). As described above with respect to FIG. 6, first driving circuit 133, which may be regarded as the third driving circuit, may be arranged, on the first direction (−x direction) side of the second display area DA2 and on a third direction (+x direction) side of the second display area DA2. The first driving circuit 133, which may be regarded as the third driving circuit on the first direction side of the second display area DA2, may be regarded as a 3^{rd}-1^{st} driving circuit. The first driving circuit 133, which may be regarded as the third driving circuit on the third direction side of the second display area DA2, may be regarded as a 3^{rd}-2^{nd} driving circuit.

Referring to FIG. 9B, the optical path control layer 500 may include a first layer 510, a plurality of light-blocking lines 530, and a second layer 550. The plurality of light-blocking lines 530 included in the optical path control layer 500 may be an example of the second light-blocking line BL2 in the plan view of FIG. 9A. The plurality of light-blocking lines 530 may be spaced apart from each other in the +x direction. The plurality of light-blocking lines 530 may include light-blocking materials.

In some embodiments, the plurality of light-blocking lines 530 may be spaced apart from each other and respectively placed on a first line lc1, a second line lc2, and a third line lc3 in the +x direction. In the plan view of FIG. 9A, the first line lc1, the second line lc2, and the third line lc3 may represent lines showing, in the cross-sectional view, the locations of the second light-blocking lines BL2 arranged on the third direction side of the pixels in even-numbered columns among the pixels. Referring to FIG. 9B, the plurality of light-blocking lines 530 positioned on the first line lc1, the second line lc2, and the third line lc3 have heights gradually increasing in the third direction (+x direction). For example, considering the viewing angle of the passenger in the passenger seat (170, see, e.g., FIG. 11A), the light-blocking line on the first line lc1 that is distant from the passenger in the +x direction of the second display area DA2 may be the lowest, the light-blocking line on the second line lc2 may be higher than the light-blocking line on the first line lc1, and the light-blocking line on the third line lc3 may be lower than the light-blocking line on the second line lc2. For the driver in the driver's seat, it is desirable not to display images in the second display area DA2 towards the passenger seat according to the privacy mode. As the above-described features are applied to the second display area DA2 towards the driver's seat, manufacturing costs of the light-blocking lines may be reduced, compared to the case where all of the plurality of light-blocking lines 530 have the same height.

FIG. 10 is an enlarged view of a third display area of a display apparatus, according to some embodiments of the present disclosure.

In the third display area DA3 of the display apparatus located on the center fascia 1500, a first sub-pixel PX3b, a second sub-pixel PX3g, and a third sub-pixel PX3r may be arranged. In some embodiments, the first sub-pixel PX3b, the second sub-pixel PX3g, and the third sub-pixel PX3r in the third display area DA3 may be arranged differently from the sub-pixels in the first display area DA1 and the second display area DA2. In addition, a plurality of light-blocking lines may not be included. Therefore, the light emitted from the third display area DA3 may scatter without any components in the +x direction and the −x direction being removed.

Referring to FIG. 10, the plurality of first sub-pixels PX3b may be aligned in a first column C1 in the second direction. In a second column C2, a set of a second sub-pixel PX3g and a third sub-pixel PX3r may be alternately arranged in the second direction (+y direction). In a third column C3 adjacent to the second column C2 and in a fourth column C4 adjacent to the third column C3, the arrangements of the first sub-pixel PX3b, the second sub-pixel PX3g, and the third sub-pixel PX3r may be repeated in the first direction and/or the second direction. A fifth driving circuit may provide fifth gate signals to gate lines, which are fifth gate lines and electrically connected to pixels in the third display area DA3. The fifth driving circuit may be arranged on one side of the third display area DA3 in a direction towards the first display area DA1 or the second display area DA2.

FIGS. 11A to 11C are diagrams showing a field of vision of the displays from the driver's seat and passenger seat in a driving mode, according to some embodiments of the present disclosure.

Referring to FIG. 11A, the driver in the driver's seat 160 may recognize the image displayed in the first display area DA1 in the public mode, the image displayed in the second display area DA2 in the privacy mode, and the image displayed in the third display area DA3. In some embodiments, the second display area DA2 in the privacy mode may include a 2^{nd}-1^{st} display area DA21, where light travels to the passenger in the passenger seat 170, and a 2^{nd}-2^{nd} display area DA22, where light does not travel to the passenger in the passenger seat 170.

As described above, because the display apparatus 1 includes a driving circuit of a decoder type, a plurality of gate lines connected to the pixel PX2 in the second display area DA2 may be individually driven. Therefore, the second driving circuit (135, see, e.g., FIG. 6) may be configured to provide turn-on signals (i.e., activation signals) to the second gate lines EML1 connected to pixels in the odd-numbered columns among the pixels arranged in the 2^{nd}-1^{st} display area DA21 and provide turn-off signals (i.e., deactivation signals) to the second gate lines EML1 connected to the pixels in the odd-numbered columns among the pixels arranged in the 2^{nd}-2^{nd} display area DA22. In addition, the third driving circuit (150, see, e.g., FIG. 6) may be configured to provide turn-off signals to the third gate lines EML2 connected to pixels in the even-numbered columns among the pixels arranged in the 2^{nd}-1^{st} display area DA21 and provide turn-on signals to the third gate lines EML2 connected to the pixels in the even-numbered columns among the pixels arranged in the 2^{nd}-2^{nd} display area DA22. Accordingly, when the passenger in the passenger seat 170 looks at the second display area DA2, it may appear as an image 121 of FIG. 11B. When the driver in the driver's seat 160 looks at the second display area DA2, it may appear as an image 121 of FIG. 11C.

FIG. 11A shows that a privacy mode is implemented only in some portions of the second display area DA2 of a second display unit, but the privacy mode may also be implemented in the first display area DA1 of a first display unit.

Because no light-blocking lines are arranged in a third display area DA3 of a third display unit, the image 122 of FIG. 11C may be displayed when viewed from any direction either by the driver in the driver's seat 160 or the passenger in the passenger seat 170.

As described above, as a display apparatus according to some embodiments includes fewer light-blocking lines, high-quality images may be produced. The above effect is merely an example, and the scope of the disclosure is not limited thereto.

It will be understood that, although the terms “first”, “second”, “third”, etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section discussed below could be termed a second element, component, region, layer or section, without departing from the spirit and scope of the inventive concept.

Spatially relative terms, such as “beneath”, “below”, “lower”, “under”, “above”, “upper” and the like, may be used herein for ease of description to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. In addition, it will also be understood that when a layer is referred to as being “between” two layers, it can be the only layer between the two layers, or one or more intervening layers may also be present.

The terminology used herein is for the purpose of describing particular embodiments and is not intended to be limiting of the inventive concept. As used herein, the singular forms “a” and “an” are intended to include the plural forms as well, unless the context clearly indicates otherwise. It will be further understood that the terms “include,” “including,” “comprises,” “comprising,” “has,” “have,” and “having,” when used in this specification, specify the presence of stated features, integers, steps, operations, elements, and/or components, but do not preclude the presence or addition of one or more other features, integers, steps, operations, elements, components, and/or groups thereof.

As used herein, the term “and/or” includes any and all combinations of one or more of the associated listed items. For example, the expression “A and/or B” denotes A, B, or A and B. Expressions such as “one or more of” and “at least one of,” when preceding a list of elements, modify the entire list of elements and do not modify the individual elements of the list. For example, the expression “one or more of A, B, and C,” “at least one of A, B, or C,” “at least one of A, B, and C,” and “at least one selected from the group consisting of A, B, and C” indicates only A, only B, only C, both A and B, both A and C, both B and C, or all of A, B, and C.

Further, the use of “may” when describing embodiments of the inventive concept refers to “one or more embodiments of the inventive concept.” Also, the term “exemplary” is intended to refer to an example or illustration.

It will be understood that when an element or layer is referred to as being “on”, “connected to”, “coupled to”, or “adjacent” another element or layer, it can be directly on, connected to, coupled to, or adjacent the other element or layer, or one or more intervening elements or layers may be present. When an element or layer is referred to as being “directly on,” “directly connected to”, “directly coupled to”, “in contact with”, “in direct contact with”, or “immediately adjacent” another element or layer, there are no intervening elements or layers present.

As used herein, the term “substantially,” “about,” and similar terms are used as terms of approximation and not as terms of degree, and are intended to account for the inherent variations in measured or calculated values that would be recognized by those of ordinary skill in the art. Further, if the term “substantially” is used in combination with a feature that could be expressed using a numeric value, the term “substantially” denotes a range of +/−5% of the value centered on the value.

As used herein, the terms “use,” “using,” and “used” may be considered synonymous with the terms “utilize,” “utilizing,” and “utilized,” respectively.

When one or more embodiments may be implemented differently, a specific process order may be performed differently from the described order. For example, (i) the disclosed operations of a process are merely examples, and may involve various additional operations not explicitly covered, and (ii) the temporal order of the operations may be varied.

Unless otherwise defined, all terms (including technical and scientific terms) used herein have the same meaning as commonly understood by one of ordinary skill in the art to which the present inventive concept belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

It should be understood that embodiments described herein should be considered in a descriptive sense and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various suitable changes in form and details may be made therein without departing from the spirit and scope of the present disclosure, as defined by the following claims and equivalents thereof.

What is claimed is:

1. A display apparatus comprising:
a first display unit comprising a plurality of first pixels and light-blocking lines that are, in a plan view, located only on a first direction side of each of pixels of first pixels that are in odd-numbered columns, the light-blocking lines extending in a second direction crossing a first direction;
a first driving circuit electrically connected to first gate lines configured to provide a first gate signal to the pixels of the first pixels that are in the odd-numbered columns; and
a second driving circuit electrically connected to second gate lines configured to provide a second gate signal to pixels in even-numbered columns among the plurality of first pixels.

2. The display apparatus of claim 1, wherein the plurality of first pixels comprise a plurality of first sub-pixels configured to emit first color light, a plurality of second sub-pixels configured to emit second color light, and a plurality of third sub-pixels configured to emit third color light,
wherein the plurality of first sub-pixels are located in a third column and a fourth column,
wherein, in a plan view, the plurality of second sub-pixels and the plurality of third sub-pixels are located in a first column and a second column, and
wherein a set of a pair of second sub-pixels and a set of a pair of third sub-pixels are alternately arranged.

3. The display apparatus of claim 1, wherein the first driving circuit comprises a 1^{st}-1^{st} driving circuit arranged on a first direction side of the first display unit and a 1^{st}-2^{nd} driving circuit arranged on a third direction side of the first display unit, a third direction being opposite to the first direction.

4. The display apparatus of claim 1, wherein, in a cross-sectional view perpendicular to the second direction, the light-blocking lines have heights gradually decreasing in a third direction which is opposite to the first direction.

5. The display apparatus of claim 1, further comprising a controller,
wherein, based on a first control signal from the controller, the first driving circuit is configured to provide a turn-on signal to the first gate lines, and the second driving circuit is configured to provide a turn-off signal to the second gate lines.

6. The display apparatus of claim 5, wherein, based on a second control signal from the controller, the first driving circuit is configured to provide a turn-off signal to the first gate lines, and the second driving circuit is configured to provide a turn-on signal to the second gate lines.

7. The display apparatus of claim 6, wherein the first driving circuit and the second driving circuit comprise decoder-type driving circuits that individually drive the first gate lines and the second gate lines.

8. The display apparatus of claim 7, further comprising:
a second display unit arranged on a side of the first display unit in the first direction and comprising a plurality of second pixels and light-blocking lines that are, in a plan view, positioned only on a third direction side of each of pixels in even-numbered columns among the plurality of second pixels, a third direction being opposite to the first direction, the light-blocking lines extending in the second direction;
a third driving circuit electrically connected to third gate lines that are configured to provide a third gate signal to pixels of the first pixels that are in the odd-numbered columns; and
a fourth driving circuit electrically connected to fourth gate lines that are configured to provide a fourth gate signal to the pixels in the even-numbered columns among the plurality of second pixels.

9. The display apparatus of claim 8, wherein the third driving circuit comprises a 3^{rd}-1^{st} driving circuit arranged on a first direction side of the second display unit and a 3^{rd}-2^{nd} driving circuit arranged on the third direction side of the second display unit.

10. The display apparatus of claim 8, wherein, in a cross-sectional view perpendicular to the second direction, the light-blocking lines have heights gradually increasing in the third direction.

11. The display apparatus of claim 8, wherein, based on a third control signal from the controller, the third driving circuit is configured to provide a turn-off signal to the third gate lines, and the fourth driving circuit is configured to provide a turn-on signal to the fourth gate lines.

12. The display apparatus of claim 11, wherein, based on a fourth control signal from the controller, the third driving circuit is configured to provide a turn-on signal to the third gate lines, and the fourth driving circuit is configured to provide a turn-off signal to the fourth gate lines.

13. The display apparatus of claim 12, wherein the third driving circuit and the fourth driving circuit comprise decoder-type driving circuits that individually drive the third gate lines and the fourth gate lines.

14. The display apparatus of claim 8, further comprising:
a third display unit arranged between the first display unit and the second display unit and comprising a plurality of third pixels; and
a fifth driving circuit arranged on an edge of the third display unit in a direction towards the first display unit or the second display unit, the fifth driving circuit being connected to fifth gate lines configured to provide a fifth gate signal to the plurality of third pixels.

15. A vehicle comprising the display apparatus of claim 1.

16. The vehicle of claim 15, wherein the first display unit is arranged on a passenger side dashboard.

17. A vehicle comprising the display apparatus of claim 14.

18. The vehicle of claim 17, wherein the first display unit is arranged on a passenger side dashboard.

19. The vehicle of claim 18, wherein the second display unit is arranged on a cluster in a driver's seat.

20. The vehicle of claim 19, wherein the third display unit is arranged between the passenger side dashboard and the cluster in the driver's seat.
